(19) United States
(12) Patent Application Publication
(10) Pub. No.: US 2025/0081427 A1
(43) Pub. Date: Mar. 6, 2025

(54) SEMICONDUCTOR DEVICE AND METHOD FOR FABRICATING THE SAME

(71) Applicant: SK hynix Inc., Gyeonggi-do (KR)

(72) Inventor: Min Chul SUNG, Gyeonggi-do (KR)

(21) Appl. No.: 18/430,647

(22) Filed: Feb. 2, 2024

(30) Foreign Application Priority Data
Aug. 28, 2023 (KR) 10-2023-0112774

(51) Int. Cl. H10B 12/00; H01L 29/423; H01L 29/786

(52) U.S. Cl. CPC H10B 12/315; H10B 12/03; H10B 12/482; H10B 12/488; H10D 30/6735; H10D 30/6755; H10D 30/6757

(57) ABSTRACT

A method for fabricating a semiconductor device includes forming a cell mold including a dummy channel pattern and a plurality of mold layers over a lower structure; forming a horizontal conductive line that intersects with the dummy channel pattern; forming a dummy channel layer by trimming the dummy channel pattern; forming a data storage element that is coupled to a first side of the dummy channel layer; replacing the dummy channel layer with a channel layer; and forming a vertical conductive line that is coupled to a second side of the channel layer.

### CROSS-REFERENCE TO RELATED APPLICATIONS

The present application claims priority under 35 U.S.C 119 (a) to Korean Patent Application No. 10-2023-0112774, filed on Aug. 28, 2023, which is incorporated herein by reference in its entirety.

### BACKGROUND

### 1. Field

Various embodiments of the present invention relate to a semiconductor device, and more particularly, to a semiconductor device including three-dimensional memory cells, and a method for fabricating the semiconductor device.

### 2. Description of the Related Art

Recently, in order to cope with the demands for large capacity and miniaturization of memory devices, a technology for providing a 3D memory device in which a plurality of memory cells are stacked has been proposed. However, further improvements are needed for improved performance and reliability of these 3D memory devices.

### SUMMARY

Embodiments of the present invention are directed to a 3D semiconductor device (simply referred to hereinafter as a semiconductor device) including highly integrated memory cells, and a method for fabricating the semiconductor device.

In accordance with an embodiment of the present invention, a method for fabricating a semiconductor device includes: forming a cell mold including a dummy channel pattern and a plurality of mold layers over a lower structure; forming a horizontal conductive line that intersects with the dummy channel pattern; forming a dummy channel layer by trimming the dummy channel pattern; forming a data storage element that is coupled to a first side of the dummy channel layer; replacing the dummy channel layer with a channel layer; and forming a vertical conductive line that is coupled to a second side of the channel layer.

In accordance with another embodiment of the present invention, a method for fabricating a semiconductor device includes: forming a cell mold including a dummy channel pattern over a lower structure and a pair of cell dielectric layers disposed in upper and lower portions of the dummy channel pattern; forming a pair of horizontal level recesses that expose top and bottom surfaces of the dummy channel pattern by recessing the pair of the cell dielectric layers; forming gate dielectric layers on the exposed top and bottom surfaces of the dummy channel pattern; forming first and second horizontal conductive lines that fill the pair of the horizontal level recesses over the gate dielectric layers; forming a dummy channel layer by trimming the dummy channel pattern; forming a channel level gap between the first horizontal conductive line and the second horizontal conductive line by removing the dummy channel layer; and forming a channel layer in the channel level gap.

In accordance with another embodiment of the present invention, a semiconductor device includes: a lower structure; a horizontal layer disposed over the lower structure; horizontal conductive lines disposed in upper and lower portions of the horizontal layer, respectively; a gate dielectric layer between the horizontal conductive line and the horizontal layer; a vertical conductive line that is coupled to a first side of the horizontal layer; and a data storage element that is coupled to a second side of the horizontal layer, wherein the horizontal layer includes: a channel layer having an inner space; and an inner gap-fill layer that fills the inner space of the channel layer.

These and other features and advantages of the present invention will become better understood from the following detailed description and drawings.

### BRIEF DESCRIPTION OF THE DRAWINGS

FIG. 1A is a simplified perspective view schematic illustrating a memory cell in accordance with an embodiment of the present invention.

FIG. 1B is a simplified cross-sectional view schematic illustrating the memory cell shown in FIG. 1A.

FIG. 1C is a plan view schematic a switching element shown in FIG. 1A.

FIG. 1D is a simplified cross-sectional view schematic illustrating a memory cell in accordance with another embodiment of the present invention.

FIG. 2 is a plan view schematic illustrating a semiconductor device in accordance with an embodiment of the present invention.

FIG. 3A is a simplified perspective view schematic illustrating a memory cell array MCA1 shown in FIG. 2.

FIG. 3B is a simplified cross-sectional view schematic taken along a line A-A′ shown in FIG. 2. FIG. 3C is a cross-sectional view taken along a line B-B′ shown in FIG. 2. FIG. 3D is a cross-sectional view taken along a line C-C′ shown in FIG. 2.

FIGS. 4 to 25 illustrate a method for fabricating a semiconductor device in accordance with an embodiment of the present invention.

FIGS. 26 to 28 illustrate a method for fabricating a semiconductor device in accordance with another embodiment of the present invention.

FIGS. 29A to 29C are cross-sectional views illustrating a method for fabricating a semiconductor device in accordance with another embodiment of the present invention.

FIGS. 30 to 32 are perspective views illustrating memory cell arrays in accordance with other embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The following embodiment described below relates to a three-dimensional memory cell. Memory cells may be stacked vertically to increase memory cell density and reduce parasitic capacitance.

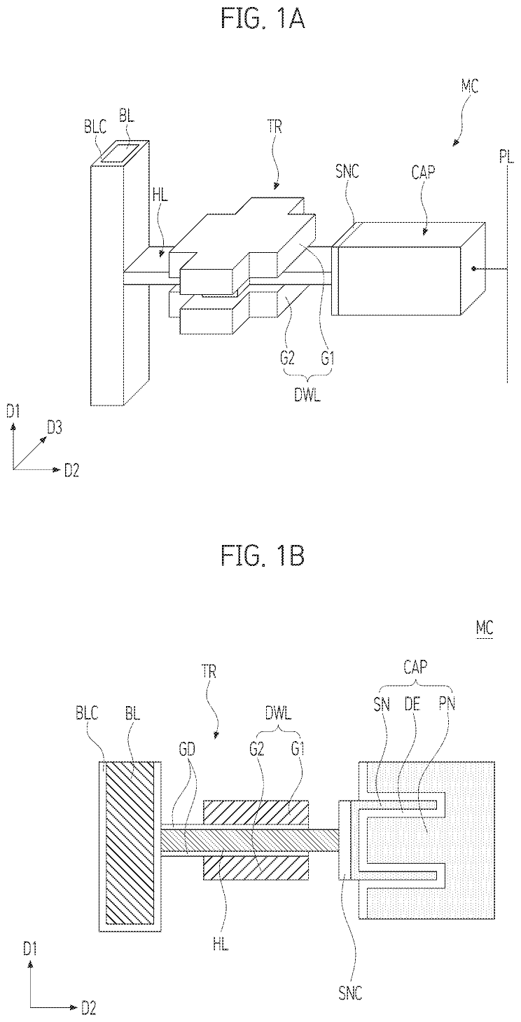

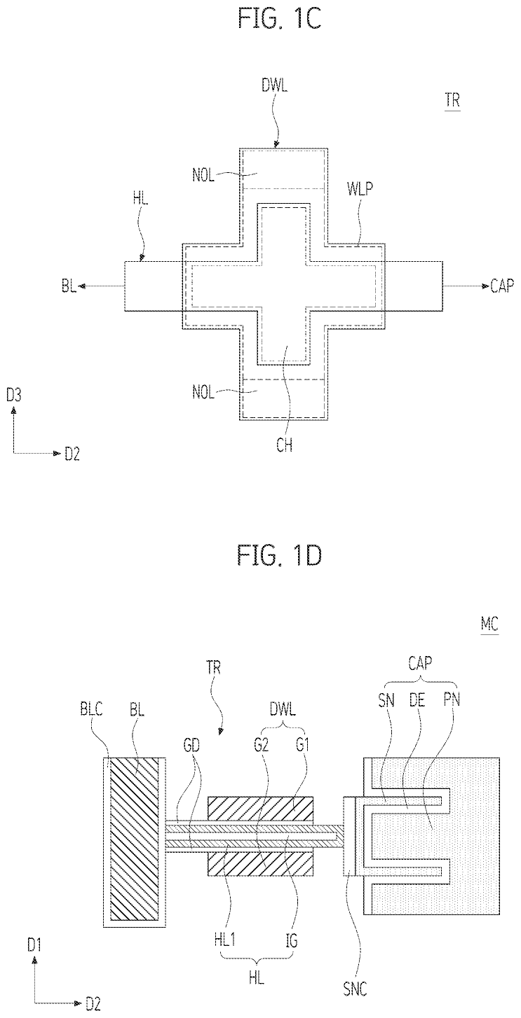

FIG. 1A is a simplified perspective view schematic illustrating a memory cell in accordance with an embodiment of the present invention. FIG. 1B is a simplified cross-sectional view schematic illustrating the memory cell shown in FIG. 1A. FIG. 1C is a plan view schematic illustrating a switching element shown in FIG. 1A.

Referring to FIGS. 1A to 1C, the memory cell MC may include a first conductive line BL, a switching element TR, and a data storage element CAP.

The first conductive line BL may be oriented in a first direction D1. The first direction D1 may be, for example, a direction perpendicular to a plane defined by second and third directions D2 and D3. In some embodiments the plane defined by the second and third directions may be a horizontal plane and the first direction may be a vertical direction. The first conductive line BL may include a bit line. The first conductive line BL may also be referred to as an upright conductive line or bit line, vertical conductive line or bit line, a vertically-oriented conductive line or bit line, a vertically-extending conductive line or bit line, or a pillar-shaped conductive line or bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include polysilicon or titanium nitride (TiN) that is doped with an N-type impurity. The first conductive line BL may include a stack (TiN/W) of titanium nitride and tungsten.

The switching element TR may have a function of controlling voltage (or current) supply to the data storage element CAP during a data write operation and a data read operation performed onto the data storage element CAP. The switching element TR may include a horizontal layer HL (also referred to more generally as a lateral layer HL), an inter-level dielectric layer GD, and a second conductive line DWL. The second conductive line DWL may include a horizontal conductive line or a horizontal word line (also referred to as a lateral conductive line or a lateral word line), and the horizontal layer HL may include an active layer. The switching element TR may include a transistor, and in this case, the second conductive line DWL may function as a gate electrode. The switching element TR may also be referred to as an access element or selection element. The second conductive line DWL may also be referred to as a horizontal gate electrode or a horizontal word line.

The horizontal layer HL may extend in the second direction D2 that intersects with the first direction D1. The second conductive line DWL may extend in the third direction D3 that intersects with the first direction D1 and the second direction D2. The first direction D1 may be a vertical direction, the second direction D2 may be a first horizontal direction (also referred to a first lateral direction), and the third direction D3 may be a second horizontal direction (also referred to as a second lateral direction). The horizontal layer HL may extend in the first horizontal direction (i.e., the second direction D2), and the second conductive line DWL may extend in the second horizontal direction (i.e., the third direction D3).

The horizontal layer HL may be horizontally oriented in the second direction D2 from the first conductive line BL. The second conductive line DWL may have a double structure. For example, the second conductive line DWL may include an upper horizontal line G1 (also referred to as upper lateral line) and a lower horizontal line G2 (also referred to as lower horizontal line) that face each other with the horizontal layer HL interposed therebetween. An inter-level dielectric layer GD may be formed on the upper and lower surfaces of the horizontal layer HL. The upper horizontal line G1 may be disposed over the horizontal layer HL. The lower horizontal line G2 may be disposed at the bottom of the horizontal layer HL. The second conductive line DWL may include a pair of an upper horizontal line G1 and a lower horizontal line G2. In the second conductive line DWL, the same driving voltage may be applied to the upper horizontal line G1 and the lower horizontal line G2. For example, the upper horizontal line G1 and the lower horizontal line G2 may form a pair and may be coupled to one memory cell MC. According to another embodiment of the present invention, different driving voltages may be applied to the upper horizontal line G1 and the lower horizontal line G2. In this case, one horizontal line between the upper horizontal line G1 and the lower horizontal line G2 may function as a back gate or a shield gate.

Referring back to FIG. 1C, each of the upper horizontal line G1 and the lower horizontal line G2 may have a width in the second direction D2, for example, the width of an overlapping portion that overlaps with the horizontal layer HL, which is greater than the width of a portion that does not overlap with the horizontal layer HL. Due to this difference in width, the second conductive line DWL may have a notch-shaped sidewall. The second conductive line DWL may include a channel overlapping portion WLP and a channel non-overlapping portion NOL. The channel overlapping portion WLP may refer to a portion that overlaps with a channel CH of the horizontal layer HL, and the channel non-overlapping portion NOL may refer to a portion that does not overlap with the horizontal layer HL. The channel overlapping portion WLP may have a cross shape or a rhombus shape.

From the perspective of a top view, the horizontal layer HL may have a cross shape or rhombus shape. According to another embodiment of the present invention, the side surfaces of the horizontal layer HL may have a bent shape or a rounded shape.

The horizontal layer HL may include a conductive metal oxide or an oxide semiconductor material. For example, the oxide semiconductor material may include Indium Gallium Zinc Oxide (IGZO).

The upper and lower surfaces of the horizontal layer HL may have a flat surface. The upper and lower surfaces of the horizontal layer HL may be parallel to each other in the second direction D2.

The horizontal layer HL may include a channel CH. The horizontal layer HL may also be referred to as a channel layer, an active layer, or a thin-body. The channel overlapping portion WLP of the channel CH and the second conductive line DWL may overlap with each other. The channel CH may have a cross shape or rhombus shape. The size of the channel overlapping portion WLP of the second conductive line DWL may be greater than that of the channel CH. The channel overlapping portion WLP of the second conductive line DWL may fully overlap with the channel CH. The channel CH may include a conductive metal oxide or an oxide semiconductor material. For example, the oxide semiconductor material may include Indium Gallium Zinc Oxide (IGZO). The channel CH of the horizontal layer HL may include an oxide semiconductor channel, for example, an IGZO channel. As will be described later, the horizontal layer HL may be formed by replacing a monocrystalline silicon layer with an oxide semiconductor material.

The inter-level dielectric layer GD may be disposed between the horizontal layer HL and the second conductive line DWL. The inter-level dielectric layer GD may also be referred to as a gate dielectric layer. The inter-level dielectric layer GD may also be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSIO, HfSiON, HfZrO, or a combination thereof. The inter-level dielectric layer GD may be formed by a thermal oxidation process of a semiconductor material.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of approximately 4.5 eV or more. The second conductive line DWL may include a stack of a low work function material and a high work function material.

The data storage element CAP may include a memory element, such as a capacitor. The data storage element CAP may be arranged horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be horizontally arranged in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. A portion of the outer surfaces of the first electrode SN may be electrically connected to the horizontal layer HL. The second electrode PN of the data storage element CAP may be coupled to a common plate PL.

A data storage element CAP may be a three-dimensional structure. The first electrode SN may have a three-dimensional structure. The first electrode SN may have a horizontal three-dimensional structure that is oriented in the second direction D2. As an example of the three-dimensional structure, the first electrode SN may have a cylindrical shape. The cylindrical shape of the first electrode SN may include a cylindrical inner surface and a cylindrical outer surface. A portion of the cylindrical outer surfaces of the first electrode SN may be electrically connected to the horizontal layer HL. A dielectric layer DE and a second electrode PN may be disposed on the cylindrical inner surfaces of the first electrode SN.

According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TIN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack (TiN/SiGe/WN) of titanium nitride/silicon germanium/tungsten nitride. In the titanium nitride/silicon germanium/tungsten nitride (TiN/SiGe/WN) stack, silicon germanium may be a gap-fill material that fills the inside of the first electrode SN, and titanium nitride (TIN) may serve as the second electrode PN of the data storage element CAP, and tungsten nitride may be a low-resistance material.

The dielectric layer DE may also be referred to as a capacitor dielectric layer or a memory layer. The dielectric layer DE may include silicon oxide, silicon nitride, a high-k material, or a combination thereof. The high-k materials may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium-based oxide (Zr-based oxide). The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and ZAZ stack may also be referred to as a zirconium oxide-based layer (ZrO₂-based layer). According to another embodiment of the present invention, the dielectric layer DE may be formed of hafnium-based oxide (Hf-based oxide). The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and HAH stack may also be referred to as hafnium oxide-based layer (HfO₂-based layer). In the ZA stack, ZAZ stack, HA stack, and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material that has a greater band gap energy than the high-k material. The dielectric layer DE may include silicon oxide (SiO₂) as a high band gap material other than aluminum oxide (Al₂O₃). Leakage current may be suppressed by containing a high band gap material in the dielectric layer DE. The high band gap material may be thinner than a high-k material. According to another embodiment of the present invention, the dielectric layer DE may include a stacked structure in which a high-k material and a high bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stack structure, aluminum oxide (Al₂O₃) may be thinner than zirconium oxide (ZrO₂) and hafnium oxide (HfO₂).

According to another embodiment of the present invention, the dielectric layer DE may include a high-k material and a high band gap material, and the dielectric layer DE may have a laminated structure in which a plurality of high-k materials and a plurality of high band gap materials are stacked, or a mixed structure in which a high-k material and a high band gap material are intermixed.

According to another embodiment of the present invention, the dielectric layer DE may include a ferroelectric material, an anti-ferroelectric material, or a combination thereof. For example, the dielectric layer DE may include HfZrO.

According to another embodiment of the present invention, the dielectric layer DE may include a combination of a high-k material and a ferroelectric material, a combination of a high-k material and an anti-ferroelectric material, or a combination of a high-k material or a ferroelectric material and an anti-ferroelectric material.

According to another embodiment of the present invention, an interface control layer may be further formed between the first electrode SN and the dielectric layer DE to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a metal-insulator-metal (MIM) capacitor. The data storage element CAP may be replaced by another data storage material. For example, the data storage material may be a thyristor, a phase-change material, a magnetic tunnel junction MTJ, or a variable resistance material. For example, the memory cell MC may include a thyristor, the first conductive line BL may be a cathode line, and the data storage element CAP may be replaced by an anode line. Accordingly, the horizontal layer HL may include four semiconductor layers that are stacked in the second direction D2. The thyristor may include a first diode and a second diode that are coupled serially. When a forward bias of the same voltage is applied to the thyristor, the thyristor may have a high conductance state in which a large amount of current flows, or a low conductance state in which a small amount of current flows or no current flows. The memory cell MC according to this embodiment of the present invention may have a “1” state and a “0” state by using the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon. The first and second contact nodes BLC and SNC may include a conductive metal nitride or a conductive metal oxide. For example, the first and second contact nodes BLC and SNC may include TIN, indium zinc oxide (IZO), indium tin oxide (ITO), or a combination thereof. According to another embodiment of the present invention, the second contact node SNC may be omitted. When the first and second contact nodes BLC and SNC contain metal oxides such as IZO, ITO, etc., the contact resistance between the first and second contact nodes BLC and SNC and the horizontal layer HL may be improved.

FIG. 1D is a simplified cross-sectional view schematic illustrating a memory cell in accordance with another embodiment of the present invention. The memory cell MC1 of FIG. 1D may be similar to the memory cell MC of FIGS. 1A to 1C. Hereinafter, repetitive detailed descriptions of the constituent elements also appearing in FIGS. 1A to 1C may be omitted.

Referring to FIG. 1D, the memory cell MC1 may include a first conductive line BL, a switching element TR, and a data storage element CAP arranged along the second direction in the recited order. The switching element TR may include a horizontal layer HL and a second conductive line DWL. The second conductive line DWL may include a pair of an upper conductive line G1 and a lower conductive line G2. The data storage element CAP may include a first electrode SN, a second electrode PN, and a dielectric layer DE disposed between the first and second electrodes SN, and PN.

The horizontal layer HL may include a channel layer HL1 and an inner gap-fill layer IG. The channel layer HL1 may have a cup shape positioned in a sideways orientation with the bottom surface of the cup contacting the second node contact SNC and an open space of the cup being adjacent to the bit line contact BLC. An inner space within the cup-shape is filled with the inner gap-fill layer IG. Hence the inner gap-fill layer IG is in direct contact with the bit line contact BLC but not with the second node contact SNC. The channel layer HL1 may include a conductive material, and the inner gap-fill layer IG may include a dielectric material. The channel layer HL1 may include a conductive metal oxide or an oxide semiconductor material. The channel layer HL1 may include IGZO. The inner gap-fill layer IG may include silicon oxide, silicon nitride, an air gap, or a combination thereof.

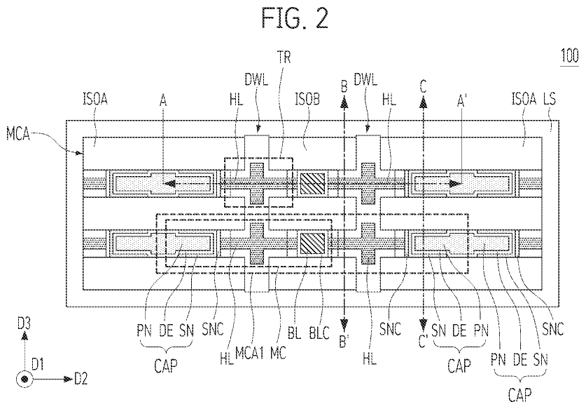

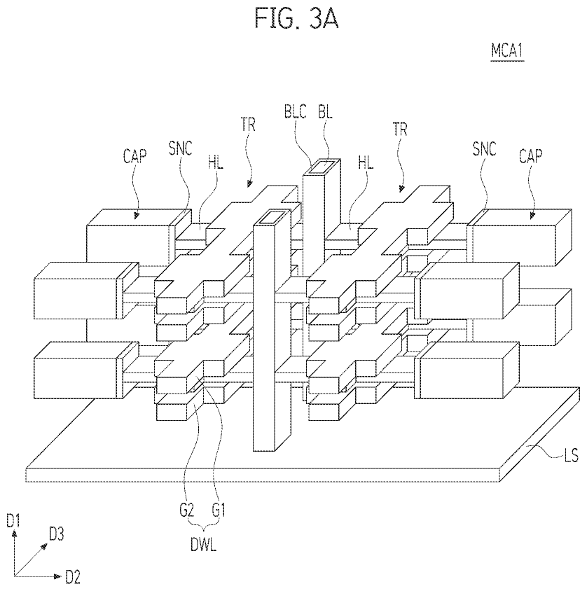

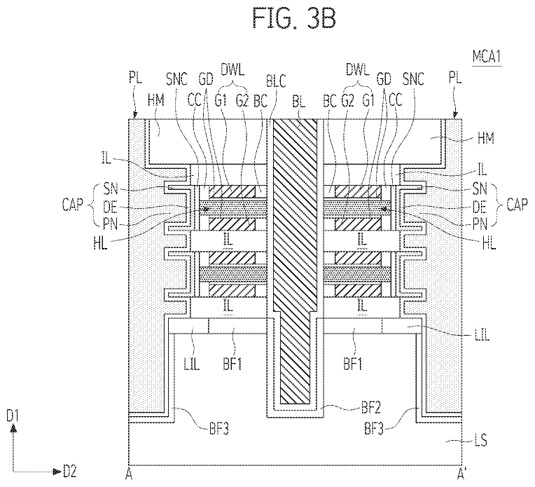

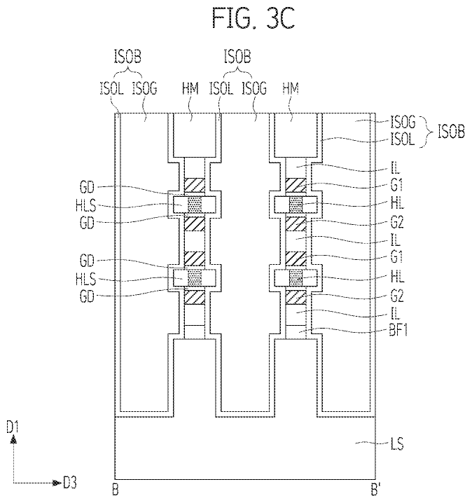

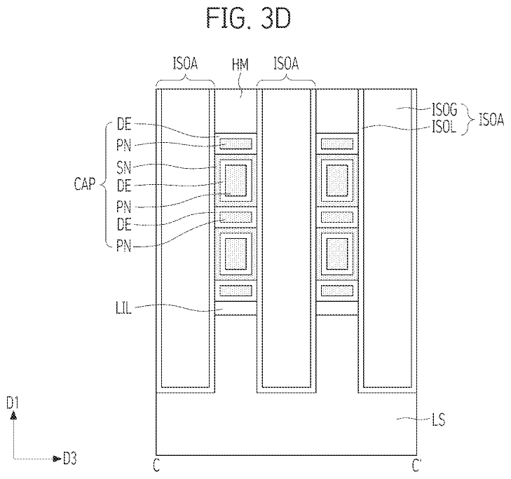

FIG. 2 is a plan view schematic illustrating a semiconductor device in accordance with an embodiment of the present invention. FIG. 3A is a simplified perspective view schematic illustrating a first memory cell array MCA1 shown in FIG. 2. FIG. 3B is a simplified cross-sectional view schematic taken along a line A-A′ shown in FIG. 2. FIG. 3C is a cross-sectional view taken along a line B-B′ shown in FIG. 2, and FIG. 3D is a cross-sectional view taken along a line C-C′ shown in FIG. 2.

Referring to FIGS. 2, 3A, 3B, 3C, and 3D, the semiconductor device 100 may include a memory cell array MCA. The memory cell array MCA may include a plurality of memory cells MC. As for the individual memory cells MC, FIGS. 1A to 1C may also be referred to. Each memory cell MC may include a first conductive line BL, a switching element TR, and a data storage element CAP.

A memory cell array MCA may include a three-dimensional array of memory cells MC. The three-dimensional array of memory cells MC may include a column array of memory cells MC and a row array of memory cells MC. The column array of the memory cells MC may include a plurality of memory cells MC that are stacked in the first direction D1. T. The row array of the memory cells MC may include a plurality of memory cells MC that are horizontally arranged in the second direction D2 and the third direction D3. The memory cell array MCA may include sub-memory cell arrays MCA1 that are adjacent to each other in the second direction D2. The sub-memory cell array MCA1 may have a mirror-type structure in which two memory cells MC share the first conductive line BL. According to another embodiment of the present invention, the semiconductor device 100 may further include sub-memory cell arrays having a mirror-type structure in which two memory cells MC share the second electrode PN of the data storage element CAP. The memory cell array MCA may include a plurality of sub-memory cell arrays MCA1 in which memory cells MC are vertically stacked in the first direction D1. The memory cell array MCA may include a plurality of sub-memory cell arrays MCA1 that are horizontally arranged in the third direction D3.

Inter-cell dielectric layers IL may be disposed between the memory cells MC that are stacked in the first direction D1. The inter-cell dielectric layers IL may include silicon oxide. The inter-cell dielectric layers IL may also be referred to as horizontal inter-cell dielectric layers.

Cell isolation layers ISOA and ISOB may be disposed between the neighboring memory cells MC that are disposed in the third direction D3. The cell isolation layers ISOA and ISOB may also be referred to as vertical inter-cell dielectric layers. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first and second cell isolation layers ISOA and ISOB may extend vertically in the first direction D1. The first and second cell isolation layers ISOA and ISOB may have a pillar structure extending vertically in the first direction D1. The first and second cell isolation layers ISOA and ISOB may be alternately disposed in the second direction D2. The first cell isolation layers ISOA may be disposed between the data storage elements CAP in the third direction D3. The second cell isolation layers ISOB may be disposed between the first conductive lines BL in the third direction D3. The second conductive line DWL may be disposed between the first and second cell isolation layers ISOA and ISOB in the second direction D2. Each of the first and second cell isolation layers ISOA and ISOB may include a stack of a cell isolation liner layer ISOL and a cell isolation gap-fill layer ISOG. The cell isolation liner layers ISOL may include silicon oxide. The cell isolation gap-fill layers ISOG may include silicon carbon oxide.

The memory cell array MCA may be disposed over the lower structure LS.

The memory cell array MCA may include a plurality of second conductive lines DWL that are vertically stacked in the first direction D1. The memory cell array MCA may include a plurality of horizontal layers HL that are stacked vertically in the first direction D1. The memory cell array MCA may include a plurality of data storage elements CAP that are vertically stacked in the first direction D1. The memory cell array MCA may include a plurality of first conductive lines BL that are spaced apart from each other in the third direction D3.

Each of the second conductive lines DWL may include a channel overlapping portion WLP and a channel non-overlapping portion NOL as illustrated in FIG. 1C. The channel overlapping portion WLP may have a cross shape or rhombus shape. The channel overlapping portion WLP may fully overlap with the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notch-shaped sidewall.

A plurality of first passivation layers BF1 may be disposed between the lowermost second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2 and BF3 may include a dielectric material. The first to third passivation layers BF1, BF2 and BF3 may include silicon oxide. The first to third passivation layers BF1, BF2 and BF3 may electrically disconnect the first conductive line BL, the second conductive lines DWL, and the data storage elements CAP from the lower structure LS. The first to third passivation layers BF1, BF2 and BF3 may also be referred to as bottom dielectric layers or bottom passivation layers. A lowermost level inter-cell dielectric layer LIL may be disposed between the first passivation layers BF1 and the data storage element CAP.

The first conductive lines BL may extend vertically in the first direction D1 from the upper portion of the lower structure LS. The horizontal layers HL may extend in the second direction D2 that intersects with the first direction D1. The second conductive lines DWL may extend in the third direction D3 that intersects with the first direction D1 and the second direction D2.

From the perspective of a top view, the horizontal layers HL may have a cross shape or rhombus shape. According to another embodiment of the present invention, the side surfaces of the horizontal layer HL may have a bent shape or a round shape. As illustrated in FIG. 1B, the horizontal layer HL may include a channel CH.

The first capping layer BC may be disposed between the second conductive line DWL and the first conductive line BL. A second capping layer CC may be disposed between the second conductive line DWL and the first electrode SN of the data storage element. The first capping layer BC may be disposed between the upper horizontal line G1 and the first conductive line BL, and also, the first capping layer BC may be disposed between the lower horizontal line G2 and the first conductive line BL. The second capping layer CC may be disposed between the upper horizontal line G1 and the first electrode SN of the data storage element CAP, and also, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride.

Each memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon. The first and second contact nodes BLC and SNC may include TIN, indium zinc oxide (IZO), indium tin oxide (ITO), or a combination thereof. According to another embodiment of the present invention, the second contact node SNC may be omitted.

The horizontal layers HL of the switching elements TR disposed horizontally in the third direction D3 may share one second conductive line DWL. The horizontal layers HL of the switching elements TR arranged horizontally in the third direction D3 may be coupled to different first conductive lines BL. Switching elements TR stacked in the first direction D1 may share one first conductive line BL. Switching elements TR arranged horizontally in the third direction D3 may share one second conductive line DWL.

The first cell isolation layers ISOA may be disposed between the first electrodes SN of the data storage elements CAP in the third direction D3. The first electrodes SN may be separated from each other by the first cell isolation layers ISOA. The second electrodes PN of the data storage elements CAP may be coupled to a common plate PL.

The lower structure LS may include a semiconductor substrate, a metal interconnection structure, a dielectric structure, a conductive structure, a bonding pad structure, another memory or a peripheral circuit portion.

For example, the lower structure LS may include a structure in which a peripheral circuit portion, a metal interconnection structure, and a bonding pad structure are stacked in the mentioned order. The memory cell array MCA and the peripheral circuit portion of the lower structure LS may be combined by wafer bonding.

The peripheral circuit portion of the lower structure LS may be replaced at a lower level than the memory cell array MCA. This may also be referred to as COP (Cell-Over-Peripheral) structure. The peripheral circuit portion may include at least one control circuit for driving the memory cell array MCA. The at least one control circuit of the peripheral circuit portion may include an N-channel transistor, a P-channel transistor, a CMOS circuit, or a combination thereof. The at least one control circuit of the peripheral circuit portion may include an address decoder circuit, a read circuit, a write circuit, and the like. The at least one control circuit of the peripheral circuit portion may include a planar channel transistor, a recess channel transistor, a buried gate transistor, a fin channel transistor (FinFET), and the like.

For example, the peripheral circuit portion may include sub-word line drivers and a sense amplifier. The first conductive line BL may be coupled to the sense amplifier, and the second conductive lines DWL may be coupled to the sub-word line drivers.

According to another embodiment of the present invention, the peripheral circuit portion may be disposed at a higher level than the memory cell array MCA. This may also be referred to as POC (Peripheral-Over-Cell) structure.

According to another embodiment of the present invention, the memory cell array MCA may include a Dynamic Random Access Memory (DRAM), an embedded DRAM, a NAND, an FeRAM, an STTRAM, a PCRAM, or an ReRAM.

According to another embodiment of the present invention, each memory cell MC may be replaced by the memory cell MC1 of FIG. 1D.

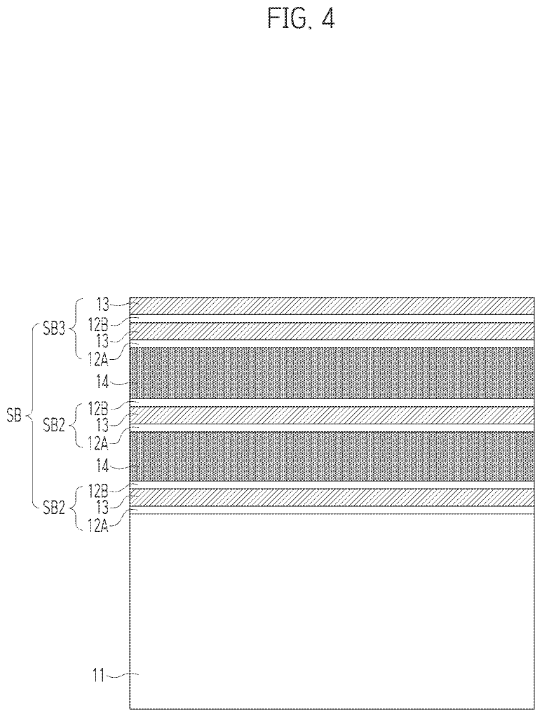

FIGS. 4 to 21 illustrate a method for fabricating a semiconductor device in accordance with embodiments of the present invention.

Referring to FIG. 4, a stacked structure SB may be formed over a lower structure 11. The lower structure 11 may be a material suitable for semiconductor processing. The lower structure 11 may include at least one of a conductive material, a dielectric material, and a semiconductive material. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure 11 may also include other semiconductor materials, such as germanium. The lower structure 11 may include a III/V-group semiconductor substrate, for example, a compound semiconductor substrate, such as GaAs. The lower structure 11 may include a silicon-on-insulator (SOI) substrate.

The stacked structure SB may include a plurality of sub-stacks that are alternately stacked. Each of the sub-stacks may include a first layer 12A, a second layer 13, a third layer 12B, and a dummy channel material layer 14 that are stacked in the mentioned order. The first layers 12A and the third layers 12B may be of the same material and may include silicon germanium. The second layers 13 and the dummy channel material layers 14 may include monocrystalline silicon. The first layers 12A, second layers 13, third layers 12B, and dummy channel material layer 14 may be formed by an epitaxial growth process. The first layer 12A at the lowermost level may serve as a seed layer during the epitaxial growth process. The first layers 12A may be thinner than the second layers 13, and the dummy channel material layers 14 may be thicker than the second layers 13.

The stacked structure SB may include a plurality of dummy channel material layers 14, a first sacrificial layer stack SB1, a second sacrificial layer stack SB2, and a third sacrificial layer stack SB3. The stacked structure SB may include the first sacrificial layer stack SB1, the dummy channel material layer 14, the second sacrificial layer stack SB2, the dummy channel material layer 14, and the third sacrificial layer stack SB3 that are stacked in the mentioned order. The second layer 13 may be disposed at the uppermost level of the stacked structure SB. Each of the first sacrificial layer stack SB1, the second sacrificial layer stack SB2, and the third sacrificial layer stack SB3 may be a triple layer stack of the first layer 12A/second layer 13/third layer 12B. For example, when the first layer 12A and the third layer 12B include a silicon germanium layer and the second layer 13 includes a monocrystalline silicon layer, the first sacrificial layer stack SB1, the second sacrificial layer stack SB2 and the third sacrificial layer stack SB3 may include a stack (SiGe/Si/SiGe) of a first silicon germanium layer/monocrystalline silicon layer/second silicon germanium layer. The third sacrificial layer stack SB3 may be a quadruple layer of the first layer 12A/second layer 13/third layer 12B/second layer 13. The third sacrificial layer stack SB3 may be used as a hard mask.

The second layers 13 may include a first monocrystalline silicon layer, and the dummy channel material layers 14 may include a second monocrystalline silicon layer. Accordingly, the stacked structure SB may include the first sacrificial layer stack SB1 which is disposed below the second monocrystalline silicon layer, and the second sacrificial layer stack SB2 which is disposed over the second monocrystalline silicon layer. Each of the first and second sacrificial layer stacks SB1 and SB2 may include a stack of a first silicon germanium layer/first monocrystalline silicon layer/second silicon germanium layer. The second monocrystalline silicon layer may be thicker than the first monocrystalline silicon layer.

The first layers 12A, second layers 13, and third layers 12B may also be referred to as ‘sacrificial layers’, and the dummy channel material layers 14 may also be referred to as recess target layers.

The stacked structure SB may also be referred to as a vertical stack. The stacked structure SB may be formed by alternating a plurality of sacrificial layers and the recess target layers. The sacrificial layers may include a first stack SB1, a second stack SB2, and a third stack SB3, and each of the first stack SB1, the second stack SB2, and the third stack SB3 may include a stack of the first layer 12A/second layer 13/third layer 12B. The recess target layers may include dummy channel material layers 14. Each of the sacrificial layers may include a stack of a first silicon germanium layer/first monocrystalline silicon layer/second silicon germanium layer, and each of the recess target layers may include a second monocrystalline silicon layer, wherein the second monocrystalline silicon layer may be thicker than the first monocrystalline silicon layers.

As described in the above-described embodiments of the present invention, when memory cells are stacked, the first sacrificial layer stack SB1, the dummy channel material layer 14, the second sacrificial layer stack SB2, and the dummy channel material layer 14, and the third sacrificial layer stack SB3 may be alternately stacked several times.

According to another embodiment of the present invention, the dummy channel material layers 14 may include amorphous silicon or polysilicon.

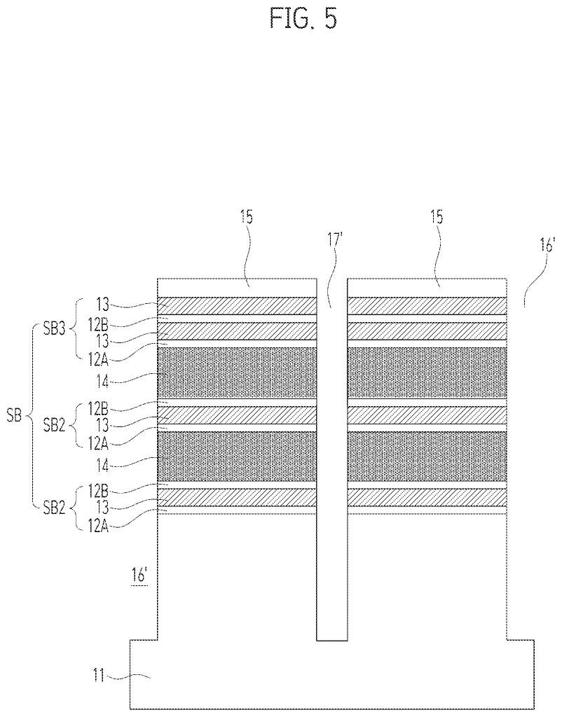

Referring to FIG. 5, a hard mask layer pattern 15 may be formed over the stacked structure SB. The hard mask layer pattern may include silicon nitride. The hard mask layer pattern 15 may be formed by an etching process using a mask layer (not shown). The hard mask layer pattern 15 may include a plurality of hole-type openings defined therein. The hard mask layer pattern 15 may be formed using a double patterning process.

Portions of the stacked structure SB may be etched using the hard mask layer pattern 15 as an etch barrier. Accordingly, a plurality of sacrificial vertical openings 16′ and 17′ may be formed in the stacked structure SB. The sacrificial vertical openings 16′ and 17′ may include first sacrificial vertical openings 16′ and second sacrificial vertical openings 17′. The first sacrificial vertical openings 16′ and the second sacrificial vertical openings 17′ may be hole-type openings. The first sacrificial vertical openings 16′ and the second sacrificial vertical openings 17′ may extend vertically in the first direction D1. From the perspective of a top view, the cross-sections of the first and second sacrificial vertical openings 16′ and 17′ may be a square shape, a circular shape or an oval shape.

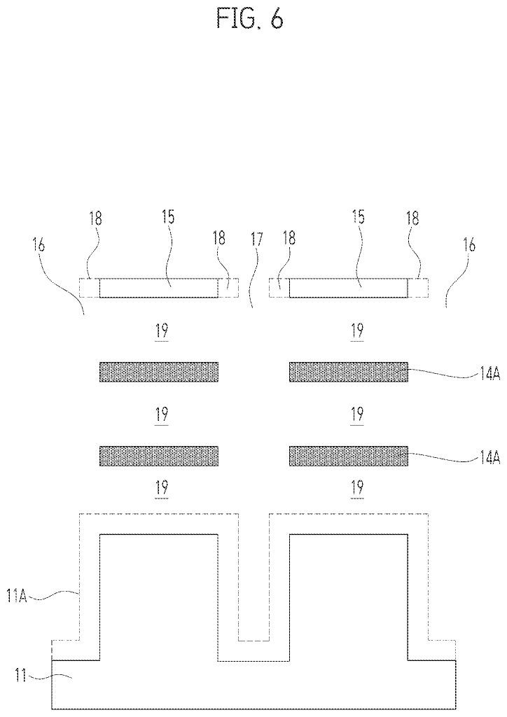

Referring to FIG. 6, a portion of the hard mask layer pattern 15 may be trimmed (see reference numeral 18).

Subsequently, the first and third layers 12A and 12B may be selectively removed through the first and second sacrificial vertical openings 16′ and 17′. The first layers 12A and the third layers 12B may be selectively removed based on the difference in the etch selectivities of the second layers 13 and the dummy channel material layers 14 and the first and third layers 12A and 12B. The first layers 12A and the third layers 12B may be removed using a wet etching process or a dry etching process. For example, when the first layers 12A and the third layers 12B include a silicon germanium layer and the second layers 13 and the dummy channel material layers 14 include a monocrystalline silicon layer, the silicon germanium layers may be etched using an etchant or an etchant gas having a selectivity with respect to the monocrystalline silicon layers.

Subsequently, a recess process may be performed to remove the second layers 13. To recess the second layers 13, a wet etching process or a dry etching process may be used. According to this embodiment of the present invention, the dummy channel material layers 14 may be partially etched while the second layers 13 are removed. Accordingly, the second layers 13 may be removed, and the dummy channel material layers 14 may be thinned, as indicated by a reference numeral ‘14A’. The recess process for forming the thinned dummy channel material layers 14, that is, the dummy channel patterns 14A, may also be referred to as a thinning process or a trimming process of the dummy channel material layers 14. To form the dummy channel patterns 14A, the top, bottom, and side surfaces of the dummy channel material layers 14 may be recessed. The dummy channel patterns 14A may include a monocrystalline silicon layer. The recess process for forming the dummy channel patterns 14A may use, for example, HSC1 (Hot SC-1). HSC1 may include a solution of ammonium hydroxide (NH₄OH), hydrogen peroxide (H₂O₂), and water (H₂O) that are mixed at a ratio of approximately 1:4:20. The second layers 13 and the dummy channel material layers 14 may be selectively etched using HSC1.

The dummy channel patterns 14A may be formed by a recess process that is performed onto the dummy channel material layers 14 as described above, and horizontal recesses 18 may be formed between the vertically disposed dummy channel patterns 14A. Each of the top and bottom surfaces of the dummy channel patterns 14A may include a flat surface.

From the perspective of a top view, the dummy channel patterns 14A may have a cross shape. The side surfaces of the dummy channel patterns 14A may have a bent shape or a rounded shape.

After the dummy channel patterns 14A are formed, the first and second sacrificial vertical openings may be expanded as indicated by reference numerals 16 and 17. The horizontally arranged dummy channel patterns 14A may be spaced apart from each other by the first and second sacrificial vertical openings 16 and 17. From the perspective of a top view, the dummy channel patterns 14A may have a shape in which a plurality of cross shapes are merged.

While the dummy channel patterns 14A are formed, the surface of the lower structure 11 may be recessed to a predetermined depth (refer to a reference numeral ‘11A’). Accordingly, the depths of the first and second sacrificial vertical openings 16 and 17 may increase.

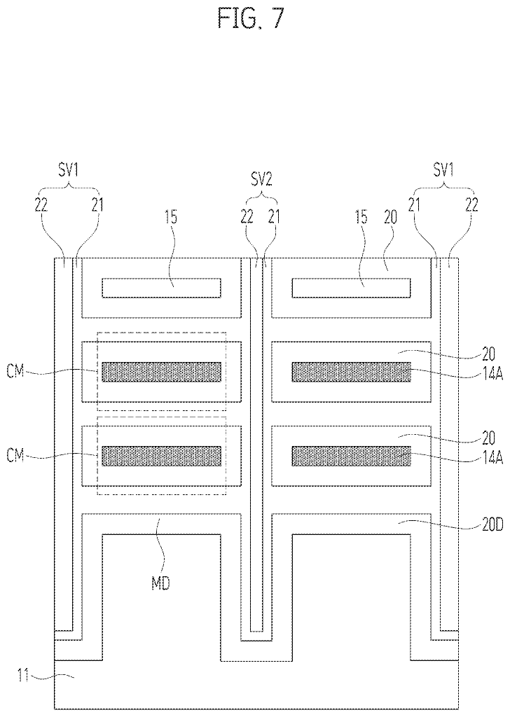

Referring to FIG. 7, first dielectric layers 20 covering the dummy channel patterns 14A may be formed. The first dielectric layers 20 may include silicon nitride. The first dielectric layers 20 may fully cover the top, bottom, and side surfaces of the dummy channel patterns 14A.

While the first dielectric layers 20 are formed, a dummy dielectric layer 19D may be formed on the surface of the lower structure 11. A portion of the first dielectric layers 20 may fully cover the top, bottom, and side surfaces of the hard mask layer pattern 15.

Subsequently, the second dielectric layer 21 may be formed over the first dielectric layers 20. The second dielectric layer 21 may fill between the vertically neighboring first dielectric layers 20. The second dielectric layer 21 may include silicon oxide. Portions of the second dielectric layer 21 may be formed conformally on the surfaces of the first and second sacrificial vertical openings 16 and 17. The horizontal recesses (see reference numeral ‘18’ shown in FIG. 6) may be filled by the first dielectric layer 20 and the second dielectric layer 21.

Subsequently, a sacrificial pillar 22 may be formed over the second dielectric layer 21 which is disposed in the first and second sacrificial vertical openings 16 and 17. The sacrificial pillar 22 may include amorphous carbon as a sacrificial material. According to another embodiment of the present invention, a pillar capping layer may be further formed over the sacrificial pillar 22. The pillar capping layer may include a metal-based material. The pillar capping layer may include titanium nitride. Forming the sacrificial pillar 22 may include depositing a sacrificial material and planarizing the sacrificial material. The planarization process for forming the sacrificial pillar 22 may be performed until the uppermost-level first dielectric layer 20 is exposed. Subsequently, the uppermost-level second dielectric layers 21 may also be planarized until the uppermost-level first dielectric layer 20 is exposed. The sacrificial pillar 22 may not be formed between the vertically stacked first dielectric layers 20.

The second dielectric layer 21 and the sacrificial pillar 22 may form first and second sacrificial pillar structures SV1 and SV2 that fill the first and second sacrificial vertical openings 16 and 17. The first sacrificial pillar structure 22 may fill the first sacrificial vertical openings 16, and the second sacrificial pillar structure SV2 may fill the second sacrificial vertical openings 17. According to another embodiment of the present invention, the first and second sacrificial pillar structures SV1 and SV2 may include a dielectric material, a carbon-containing material, a metal-based material, or a combination thereof. According to another embodiment of the present invention, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be hole-type sacrificial pillars. According to another embodiment of the present invention, portions of the first dielectric layer 20 may be conformally formed on the surfaces of the first and second sacrificial vertical openings 16 and 17. As a result, the first and second sacrificial pillar structures SV1 and SV2 may further include portions of the first dielectric layer 20.

As described above, by forming the dummy channel patterns 14A, the first dielectric layers 20, and the second dielectric layers 21, a cell mold structure may be formed. The cell mold structure may include a plurality of cell molds CM. Each cell mold CM may include a plurality of mold layers. The mold layers may refer to dummy channel patterns 14A, first dielectric layers 20, and second dielectric layers 21. Each cell mold CM may include an ONSN (Oxide-Nitride-Silicon-Nitride) stack. Here, the ONSN stack may refer to a structure in which silicon oxide, a first silicon nitride, monocrystalline silicon layer, and a second silicon nitride are sequentially stacked. The silicon oxide may correspond to the second dielectric layers 21, and the first and second silicon nitrides may correspond to the first dielectric layers 20, and the monocrystalline silicon layer may correspond to the dummy channel patterns 14A. A cell mold structure including a plurality of cell molds CM may also be referred to as a vertical stack. From another perspective, the cell mold structure may include an ONSNO (Oxide-Nitride-Silicon-Nitride-Oxide) stack. Here, the ONSNO stack may refer to a structure in which a first silicon oxide, a first silicon nitride, a monocrystalline silicon layer, a second silicon nitride, and a second silicon oxide are sequentially stacked.

As described above, through a series of the processes illustrated in FIGS. 4 to 7, the sub-stacks of the stacked structure SB may be replaced by cell molds. The first layers 12A, the second layers 13, and the third layers 12B may be replaced by the first dielectric layers 20 and the second dielectric layers 21. The dummy channel material layers 14 may become dummy channel patterns 14A through a recess process. The first dielectric layers 20 may also be referred to as a trimming target layer.

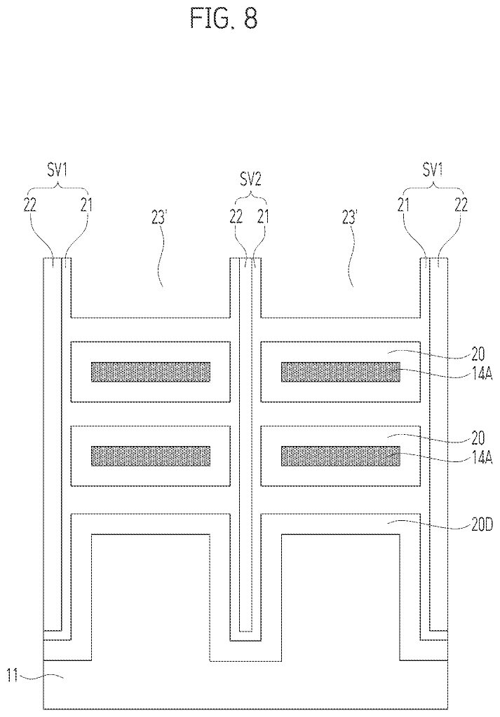

Referring to FIG. 8, the hard mask layer 15 and the uppermost level first dielectric layer 20 may be removed to form the hard mask layer level recesses 23′.

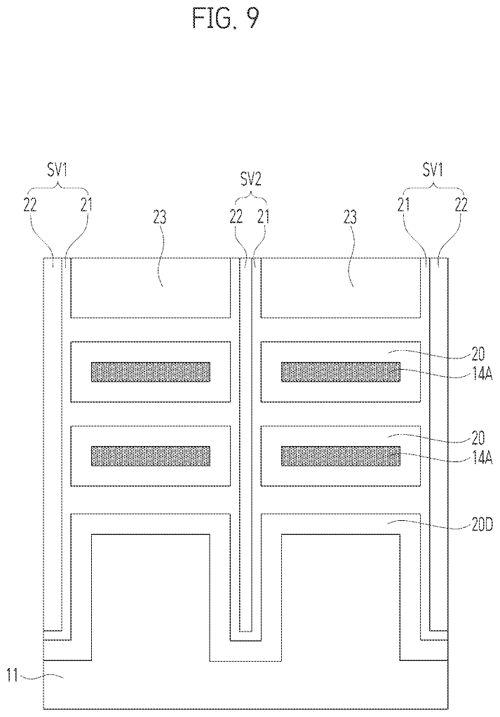

Referring to FIG. 9, a top dielectric layer 23 may be formed to fill the hard mask layer level recesses 23′. The top dielectric layer 23 may include silicon oxide.

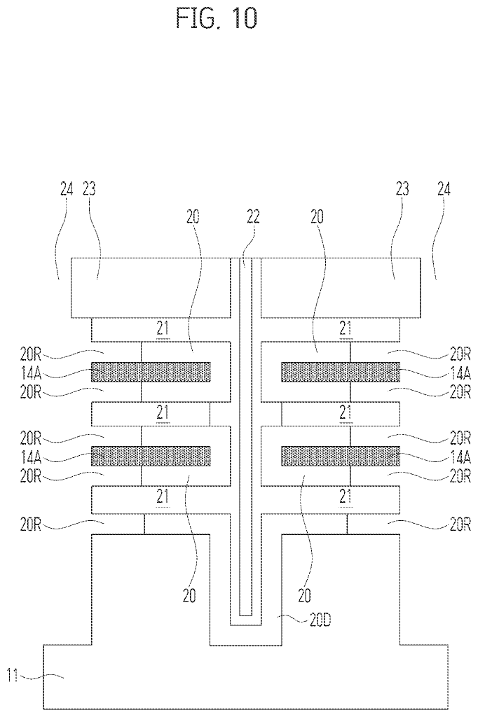

Referring to FIG. 10, the initial hole-type vertical openings 24 may be formed by removing the first sacrificial pillar structures SV1. To form the initial hole-type vertical openings 24, the second dielectric layer 21 and the sacrificial pillar 22 of the first sacrificial pillar structures SV1 may be selectively etched.

Subsequently, the second dielectric layers 21 may be horizontally recessed. Subsequently, the first dielectric layers 20 may be horizontally recessed. The amount of recess of the first dielectric layers 20 may be greater than that of the second dielectric layers 21.

First dielectric layer level recesses 20R may be formed through a recess process of the first dielectric layers 20 and may expose portions of the dummy channel patterns 14A.

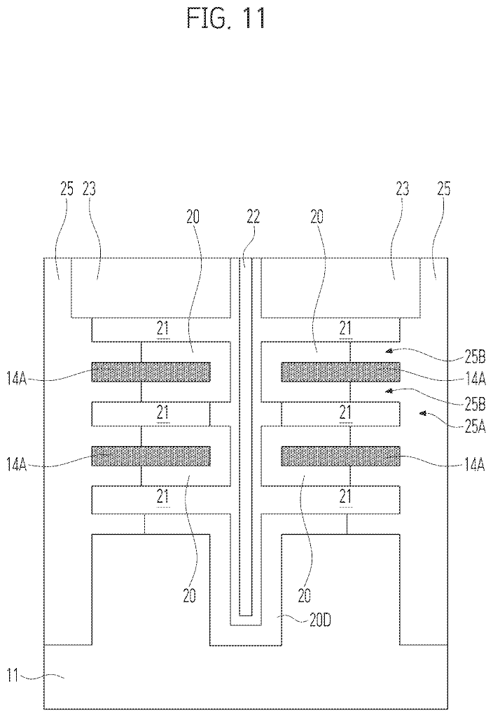

Referring to FIG. 11, first vertical sacrificial structures 25 may be formed to fill the first dielectric layer level recesses 20R and the initial hole-type vertical openings 24. The first vertical sacrificial structures 25 may include a dielectric material. The first vertical sacrificial structures 25 may include silicon oxide, silicon nitride, titanium nitride, amorphous carbon, or a combination thereof. Each of the first vertical sacrificial structures 25 may include a body portion 25A that fills the initial hole-type vertical openings 24 and expansion portions 25B that fill the first dielectric layer level recesses 20R.

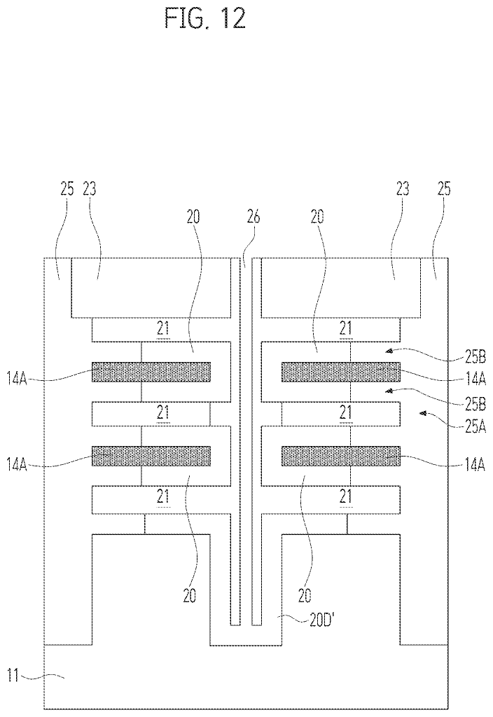

Referring to FIG. 12, in order to form a vertical level path 26, the sacrificial pillar 22 of the second sacrificial pillar structure SV2 may be removed.

Subsequently, dummy dielectric layers 20D below the vertical level path 26 may be removed to form a lower level gap 20D′.

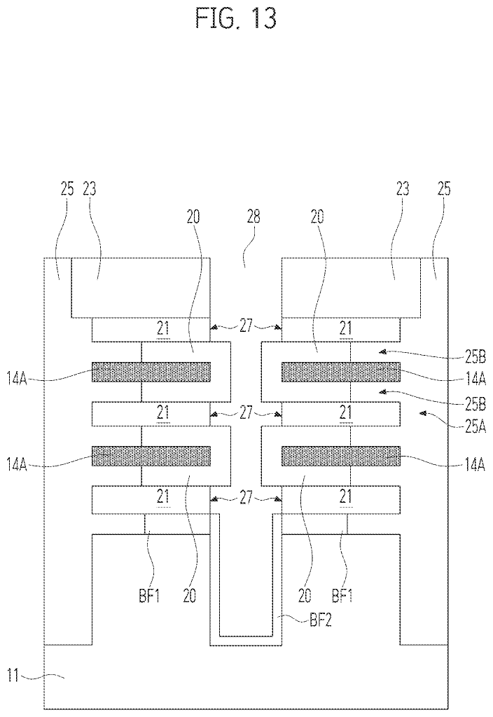

Referring to FIG. 13, the second dielectric layers 21 may be cut 27 to form the first hole-type vertical openings 28.

Subsequently, the first passivation layer BF1 and the second passivation layer BF2 may be formed to fill the lower level gap 20D′. The first passivation layer BF1 may include silicon oxide. Forming the first passivation layer BF1 may include depositing silicon oxide to fill the lower level gap 20D′ and etching the silicon oxide. The surface of the lower structure 11 may be oxidized to form the second passivation layer BF2.

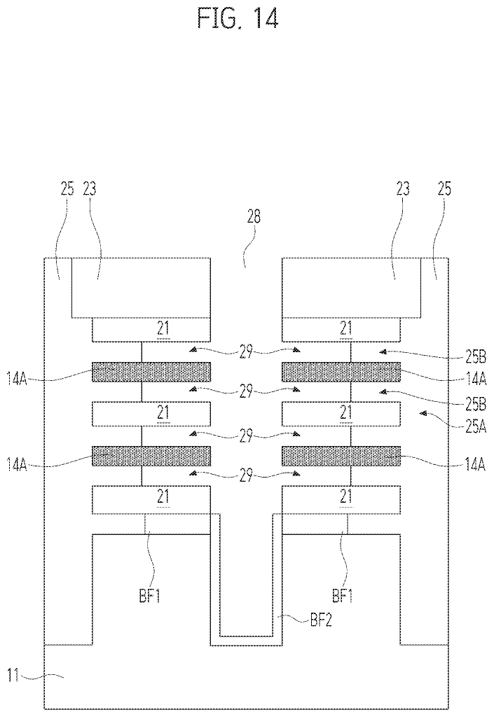

Referring to FIG. 14, the first dielectric layers 20 may be removed through the first hole-type vertical openings 28 to form horizontal level recesses 29 and expose portions (first edges) of the dummy channel patterns 14A. Hence, each dummy channel pattern 14A may be partially exposed by two adjacent horizontal level recesses 29.

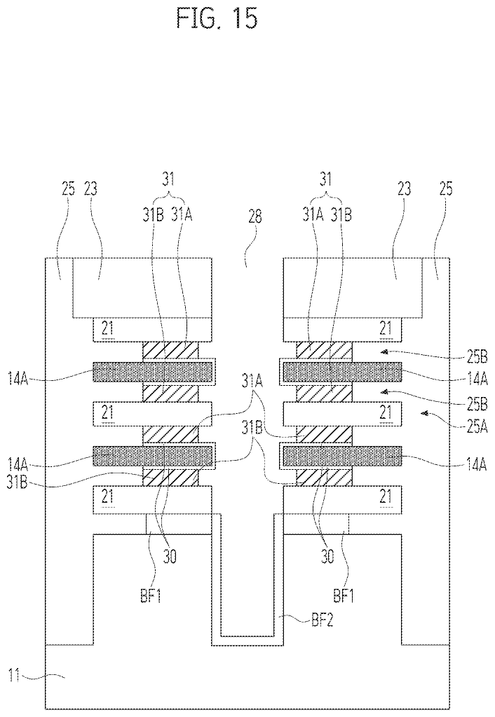

Referring to FIG. 15, an inter-level dielectric layer 30 may be formed over the exposed portions of the dummy channel patterns 14A. The inter-level dielectric layer 30 may be formed by oxidizing the surfaces of the dummy channel patterns 14A. According to another embodiment of the present invention, the inter-level dielectric layer 30 may be formed by a silicon oxide deposition process.

The inter-level dielectric layer 30 may include silicon oxide, silicon nitride, a metal oxide, a metal oxynitride, a metal silicate, a high-k material, and ferroelectric material, an anti-ferroelectric material, or a combination thereof. The inter-level dielectric layer 30 may include SiO₂, Si₃N₄, HfO₂, Al₂O₃, ZrO₂, AlON, HfON, HfSIO, HfSiON, or a combination thereof.

The inter-level dielectric layer 30 may be formed through a thermal oxidation process. For example, the inter-level dielectric layer 30 may be formed by oxidizing the surfaces of the dummy channel patterns 14A. In this way, since the inter-level dielectric layer 34 is formed through a thermal oxidation process, a high-quality inter-level dielectric layer 34 may be obtained. Silicon oxide produced by the thermal oxidation process may be of better quality than silicon oxide produced by a deposition process.

Subsequently, a horizontal conductive line 31 that fills the horizontal level recesses 29 may be formed over the inter-level dielectric layer 30. Forming the horizontal conductive line 31 may include depositing a conductive material that fills the horizontal level recesses 29 over the inter-level dielectric layer 30 and etching back the conductive material. The horizontal conductive line 31 may include a pair of first and second horizontal conductive lines 31A and 31B that are facing each other with the dummy channel pattern 14A disposed therebetween. The first and second horizontal conductive lines 31A and 31B may include a metal-based material, a semiconductor material, or a combination thereof. The first and second horizontal conductive lines 31A and 31B may include titanium nitride, tungsten, polysilicon, or a combination thereof. For example, the first and second horizontal conductive lines 31A and 31B may include a TiN/W stack in which titanium nitride and tungsten are sequentially stacked. The first and second horizontal conductive lines 31A and 31B may include an N-type work function material or a P-type work function material. The N-type work function material may have a low work function of approximately 4.5 eV or less, and the P-type work function material may have a high work function of approximately 4.5 eV or more. Referring to FIGS. 1A to 1C, each of the first and second horizontal conductive lines 31A and 31B may have a cross shape and may include a channel overlapping portion WLP. The horizontal conductive line 31 may correspond to the second conductive line DWL as illustrated in FIGS. 1A to 3B. The first and second horizontal conductive lines 31A and 31B may correspond to the upper and lower horizontal lines G1 and G2 as illustrated in FIGS. 1A to 3B.

As described above, after the dummy channel material layer 14 and the dummy channel pattern 14A are formed, a process of forming the inter-level dielectric layer 30 and a process of forming the horizontal conductive line 31 may be performed. The process of forming the inter-level dielectric layer 30 and the process of forming the horizontal conductive line 31 may be performed at a relatively higher temperature than the process of forming the dummy channel material layer 14 and the dummy channel pattern 14A.

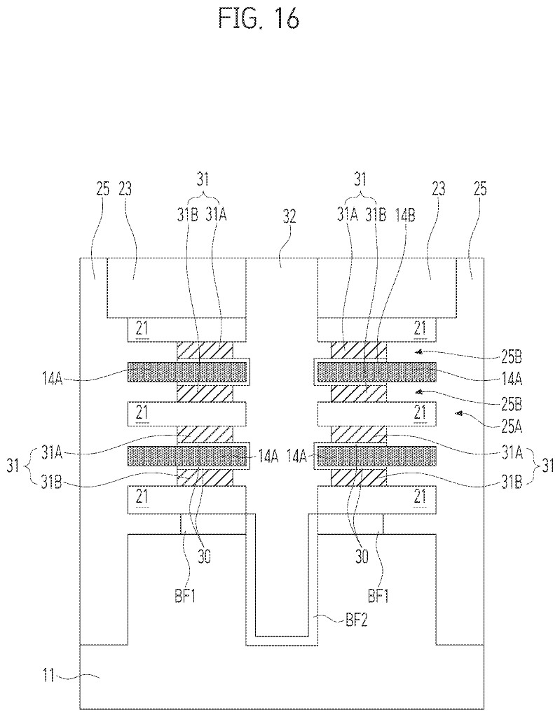

Referring to FIG. 16, a second sacrificial vertical structure 32 may be formed on first sides of the horizontal conductive lines 31 to fill the first hole-type vertical openings 28. The second sacrificial vertical structure 32 may include a dielectric material. The second sacrificial vertical structure 32 may include silicon oxide, silicon nitride, titanium nitride, amorphous carbon, or a combination thereof.

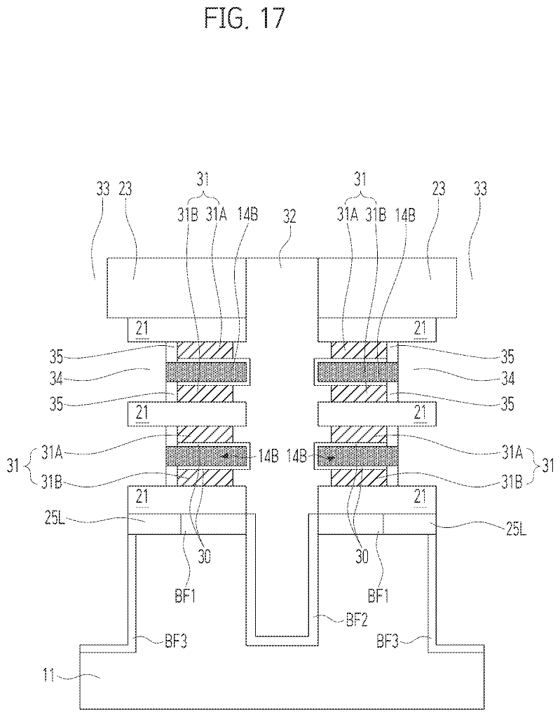

Referring to FIG. 17, second hole-type vertical openings 33 may be formed by removing the body portion 25A of the first vertical sacrificial structure 25. Subsequently, a third passivation layer BF3 may be formed on the surface of the lower structure 11. The third passivation layer BF3 may include silicon oxide.

Subsequently, the expansion portion 25B of the first vertical sacrificial structure 25 and the dummy channel patterns 14A may be horizontally trimmed from the second hole-type vertical openings 33 to form storage openings 34. Expansion portions 25B of the first vertical sacrificial structure 25 remaining after the storage openings 34 are formed may be simply referred to as a ‘first capping layer 35’, and the remaining dummy channel patterns 14A may be simply referred to as a ‘dummy channel layer 14B’. The dummy channel layer 14B may have a cross shape from the perspective of a top view. The dummy channel layer 14B may be formed through a process of trimming the dummy channel pattern 14A. The first capping layer 35 may be formed by a process of trimming the expansion portions 25B of the first vertical sacrificial structure 25.

According to some embodiments of the present invention, after the dummy channel patterns 14A are horizontally trimmed, the expansion portions 25B of the first vertical sacrificial structure 25 may be trimmed.

The storage openings 34 may also be referred to as capacitor openings.

The storage openings 34 may be disposed between the second dielectric layers 21. First capping layers 35 may be disposed in the lower and upper portions of the dummy channel layers 14B, respectively.

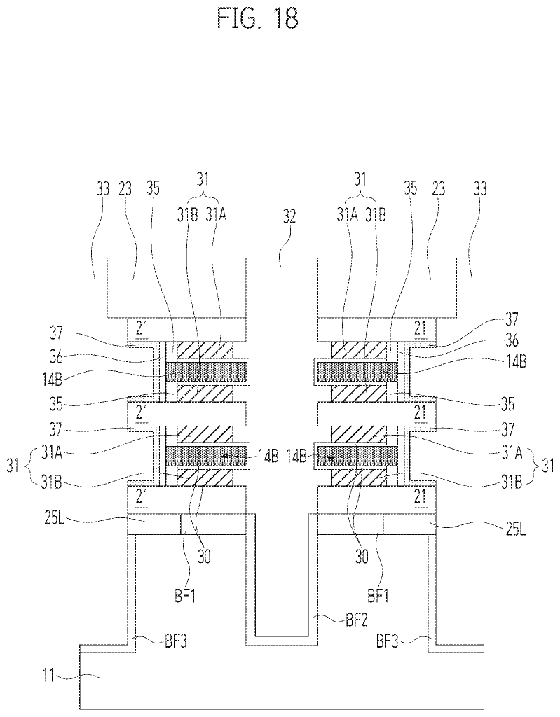

Referring to FIG. 18, a first contact node 36 may be formed over a first edge of the dummy channel layer 14B. The first contact node 36 may include a metal-based material, doped polysilicon, or a combination thereof. The first contact node 36 may include TIN, IZO, ITO, or a combination thereof.

Subsequently, the first electrode 37 of the data storage element may be formed over the first contact node 36. The first electrode 37 may have a horizontally oriented cylindrical shape. The first electrodes 37 may be disposed within the storage openings 34, respectively.

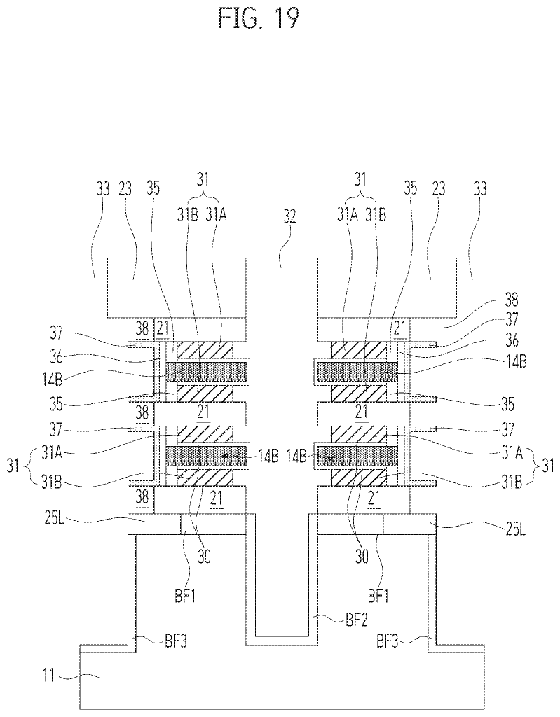

Referring to FIG. 19, the second dielectric layers 21 may be horizontally recessed (see a reference numeral ‘38’). As a result, the outer walls of the first electrode 37 may be exposed. The recessed second dielectric layers 21 may correspond to the inter-cell dielectric layer IL as illustrated in FIG. 3B.

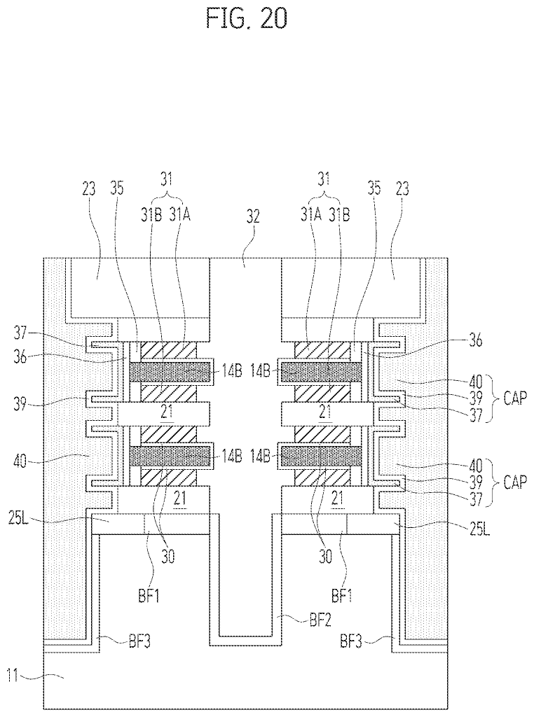

Subsequently, referring to FIG. 20, a dielectric layer 39 and a second electrode 40 may be sequentially formed over the first electrodes 37. The first electrode 37, the dielectric layer 39 and the second electrode 40 may become a data storage element CAP.

The first electrode 37 may include an inner space and a plurality of outer surfaces, and the inner space of the first electrode 37 may include a plurality of inner surfaces. The outer surfaces of the first electrode 37 may include a vertical outer surface and a plurality of horizontal outer surfaces. The inner space of the first electrode 37 may be a three-dimensional space. The dielectric layer 39 may conformally cover the inner and outer surfaces of the first electrode 37. The second electrode 40 may be disposed in the inner space of the first electrode 37 over the dielectric layer 39. A portion of the outer surfaces of the first electrode 37 may be coupled to the dummy channel layer 14B.

The first electrode 37 may have a cylindrical shape. The cylindrical shape of the first electrode 37 may include cylindrical inner surfaces and cylindrical outer surfaces. A dielectric layer 39 and a second electrode 40 may be disposed over the cylindrical inner surfaces of the first electrode 37.

The first electrode 37 and the second electrode 40 may include a metal, a noble metal, a metal nitride, a conductive metal oxide, a conductive noble metal oxide, a metal carbide, a metal silicide, or a combination thereof. For example, the first electrode 37 and the second electrode 40 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 40 may include a combination of a metal-based material and a silicon-based material. For example, the second electrode 40 may be a stack of titanium nitride/silicon germanium/tungsten nitride (TIN/SiGe/WN). In the titanium nitride/silicon germanium/tungsten nitride (TIN/SiGe/WN) stack, silicon germanium may be a gap-fill material that fills the inner space of the first electrode 37, and titanium nitride (TiN) may serve as the second electrode 40 of the data storage element CAP, and tungsten nitride may be a low-resistance material.

The dielectric layer 39 may also be referred to as a capacitor dielectric layer or a memory layer. The dielectric layer 39 may include silicon oxide, silicon nitride, a high-k material, a ferroelectric material, an anti-ferroelectric material, or a combination thereof. The dielectric layer 39 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 39 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present invention, an interface control layer for improving leakage current may be further formed between the first electrode 37 and the dielectric layer 39. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 40 and the dielectric layer 39.

As described above, after the dummy channel material layer 14 and the dummy channel pattern 14A are formed, a process of forming the inter-level dielectric layer 30, a process of forming the horizontal conductive line 31, and a process of forming the data storage element CAP may be performed. The process of forming the inter-level dielectric layer 30, the process of forming the horizontal conductive line 31, and the process of forming the data storage element CAP may be performed at a relatively higher temperature than the process of forming the dummy channel material layer 14 and the dummy channel pattern 14A.

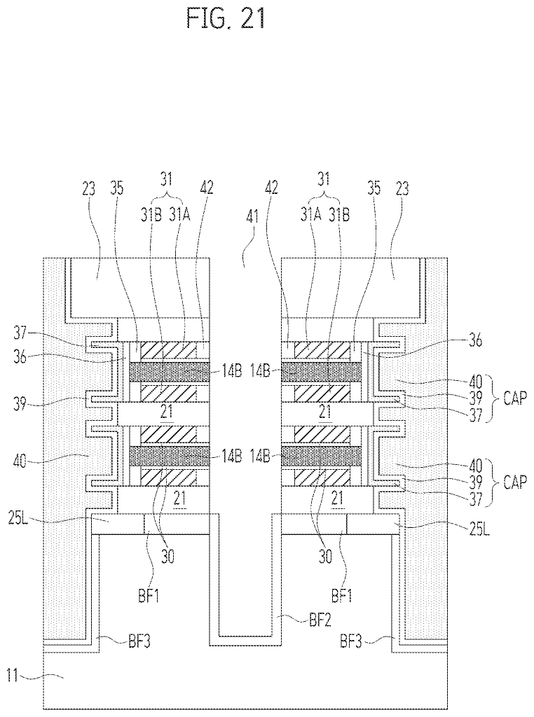

Referring to FIG. 21, the second vertical sacrificial structure 32 may be etched to form the second hole-type vertical openings 41. Portions of the second vertical sacrificial structure 32 may remain on the first side of the horizontal conductive line 31. Hereinafter, the remaining portions of the second vertical sacrificial structure 32 may be simply referred to as a second capping layer 42. The second capping layer 42 may include silicon oxide, silicon nitride, or a combination thereof.

While the second capping layer 42 is formed or after the second capping layer 42 is formed, a portion of the inter-level dielectric layer 30 may be removed to expose a second edge of each of the dummy channel layers 14B that is adjacent to the second hole-type vertical openings 41.

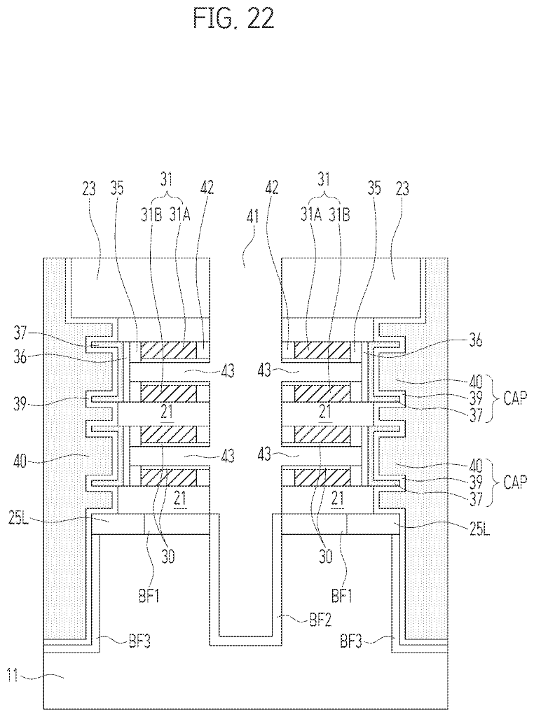

Referring to FIG. 22, channel level gaps 43 may be formed by removing the dummy channel layers 14B. Each of the channel level gaps 43 may be disposed between each pair of the first horizontal conductive line 31A and the second horizontal conductive line 31B with the inter-level dielectric layer 30 disposed on the upper (i.e., top) and lower (i.e., bottom) surfaces of each channel level gap 43. While the dummy channel layer 14B is removed, the inter-level dielectric layers 30, the first capping layers 35, and the first contact node 36 may serve as an etch barrier.

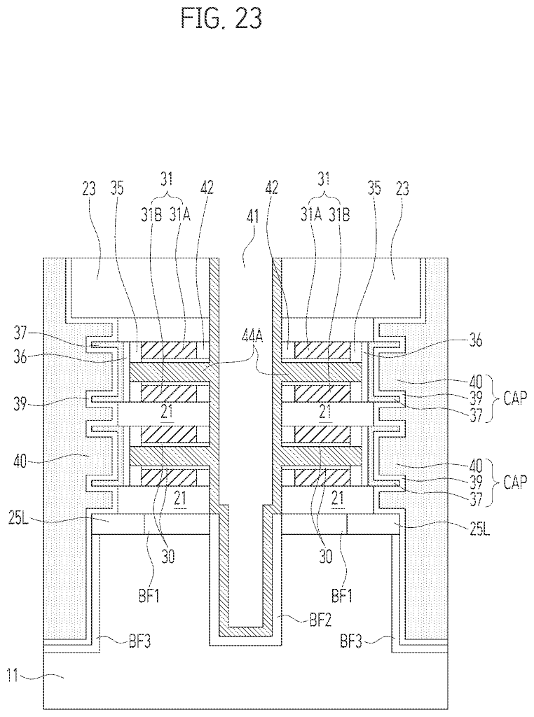

Referring to FIG. 23, a channel material layer 44A may be formed conformally to cover the walls of the second hole-type vertical openings 41 and over the channel level gaps 43 and may fill the channel level gaps 43. The channel material layer 44A may include an oxide semiconductor material, for example, IGZO. The channel material layer 44A may be a deposited channel material. The channel material layer 44A may be deposited by an Atomic Layer Deposition (ALD) method.

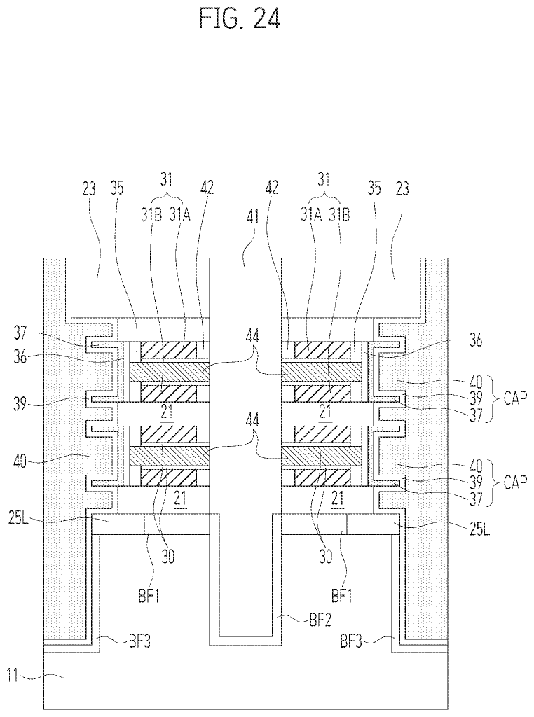

Referring to FIG. 24, a channel layer 44 may be formed by selectively etching the channel material layer 44A to remove the channel material layer 44A from the inside of the second hole-type vertical openings 41 and leaving it only inside the channel level gaps 43. Hence, the channel layer 44 may be disposed inside the channel level gaps 43.

The channel layer 44 may also be referred to as a replacement channel. The process of forming the replacement channel may include forming the dummy channel layers 14B, forming the channel level gaps 43 by removing the dummy channel layers 14B, and forming the channel layer 44 in the channel level gap 43.

A series of the processes illustrated in FIGS. 22 to 24 may be simply referred to as a ‘replacement process for the channel layer 44’, which replaces the dummy channel layer 14B with the channel layer 44.

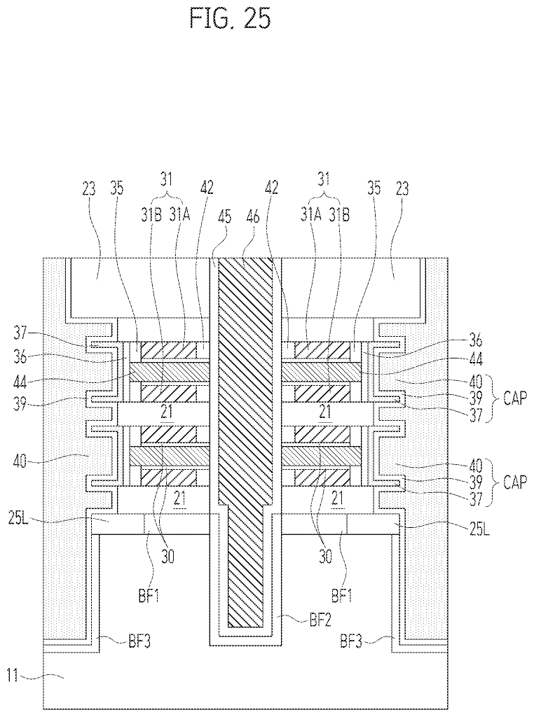

Referring to FIG. 25, a vertical conductive line 46 commonly coupled to the channel layers 44 may be formed inside the second hole-type vertical openings 41. Each of the vertical conductive lines 46 may fill a respective one of the second hole-type vertical openings 41. The vertical conductive lines 46 may include titanium nitride, tungsten, or a combination thereof. The vertical conductive line 46 may include a bit line. The vertical conductive line 46 may correspond to the first conductive line BL as illustrated in FIGS. 1A to 3B.

Before the vertical conductive line 46 is formed, a second contact node 45 may be formed. The second contact node 45 may be formed conformally on the inside of each of the second hole-type vertical openings 41 and, hence, may cover the side and bottom surfaces of the vertical conductive line 46. The second contact node may include a metal-based material or a semiconductor material. The second contact node 45 may include doped polysilicon. The second contact node 45 may include TIN, IZO, ITO, or a combination thereof.

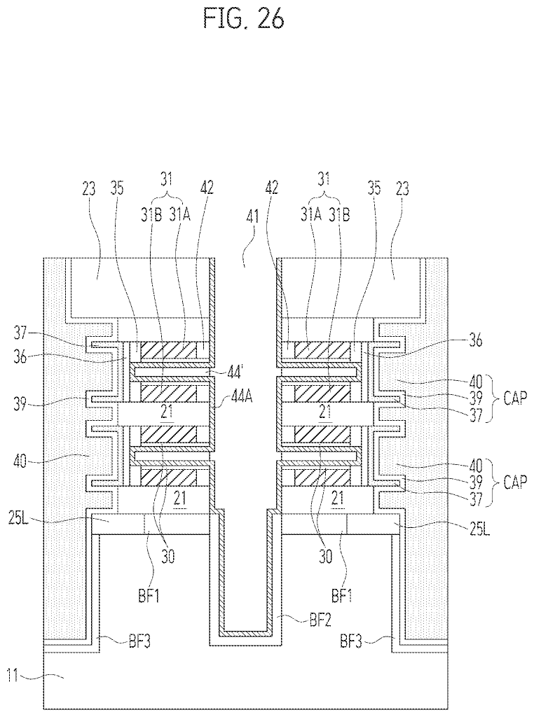

FIGS. 26 to 28 illustrate a method for fabricating a semiconductor device in accordance with another embodiment of the present invention.

First, a series of the processes as illustrated in FIGS. 4 to 22 may be performed.

After the channel level gap 43 illustrated in FIG. 22 is formed, the channel material layer 44A may be conformally formed, as illustrated in FIG. 26. Hence, the channel material layer 44A may be conformally formed inside each of the channel level gaps 43. The channel material layer 44A may only partially fill each of the channel level gaps 43. The channel material layer 44A may include an oxide semiconductor material, for example, IGZO.

An inner gap-fill layer 44′ that fills the remaining portion of the channel level gap 43 may be formed over the channel material layer 44A. The inner gap-fill layer 44′ may include a dielectric material. Forming the inner gap-fill layer 44′ may include forming an inner gap-fill material over the channel material layer 44A and etching the inner gap-fill material.

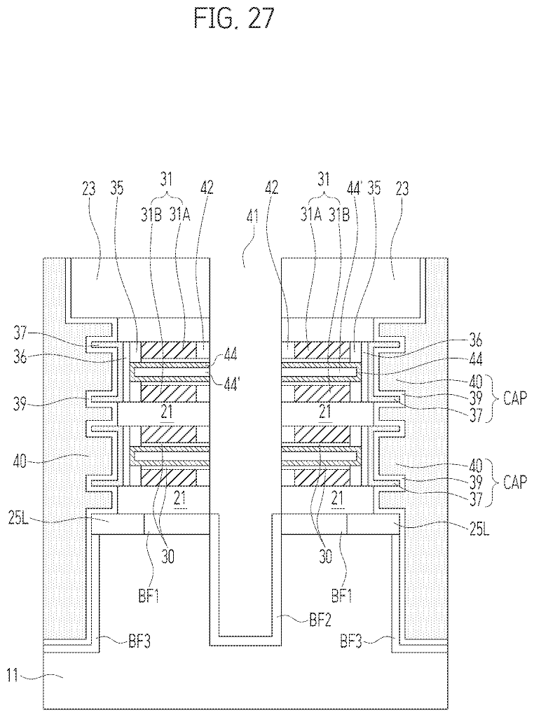

Referring to FIG. 27, the channel material layer 44A may be etched using the inner gap-fill layer 44′ as a barrier. As a result, the channel layers 44 may be formed. The cross-section of each of the channel layers 44 may have a cup shape with the inner gap-fill layer 44′ disposed in the inner space of the channel layer 44. From the perspective of a top view, as referenced in FIG. 1C, the channel layer 44 may have a cross shape.

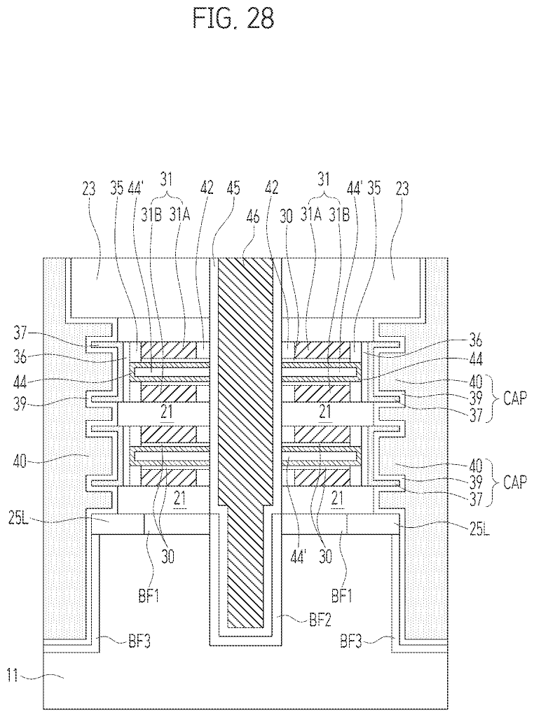

Referring to FIG. 28, a second contact node 45 and a vertical conductive line 46 may be formed.

According to the above-described embodiments of the present invention, the process of forming the dummy channel pattern 14A, high temperature processes, and the replacement process of the channel layer 44 may be sequentially performed, thereby preventing thermal deterioration of the channel layer 44. Also, since the inter-level dielectric layer 30 is formed by a thermal oxidation process, the quality of the inter-level dielectric layer 30 may be improved.

According to FIGS. 4 to 28, the method for fabricating a semiconductor device may include forming a cell mold including a dummy channel pattern 14A over the lower structure 11, forming the horizontal conductive line 31 crossing the dummy channel pattern 14A, forming the dummy channel layer 14B by trimming the dummy channel pattern 14A, forming the data storage element CAP that is coupled to the first side of the dummy channel layer 14B, replacing the dummy channel layer 14B with the channel layer 44, and forming the vertical conductive line 46 that is coupled to a second side of the channel layer 44.

Referring to FIGS. 4 to 28, a method for forming a switching element may include forming a cell mold CM including the dummy channel pattern 14A over the lower structure 11 and dielectric layers disposed in the upper and lower portions of the dummy channel pattern 14A, replacing the dielectric layers with the horizontal conductive line 31, forming the dummy channel layer 14B by trimming the dummy channel pattern 14A, and replacing the dummy channel layer 14B with the channel layer 44.

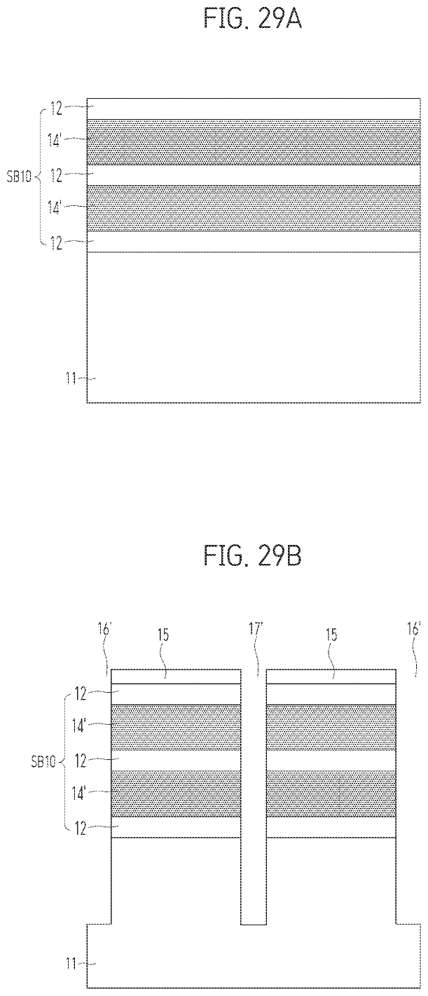

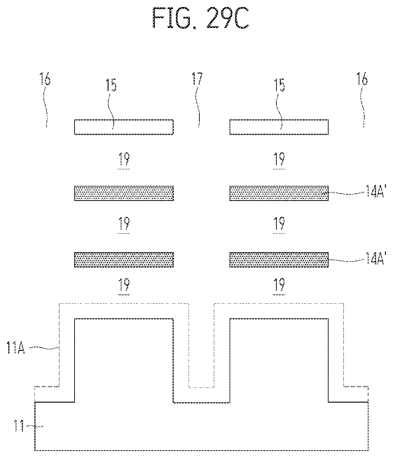

FIGS. 29A to 29C are cross-sectional views illustrating a method for fabricating a semiconductor device in accordance with another embodiment of the present invention.

Referring to FIG. 29A, a stacked structure SB10 may be formed over the lower structure 11. The stacked structure SB10 may include an alternating stack of first and second semiconductor layers. For example, the alternating stack may include a plurality of silicon germanium layers 12 and a plurality of monocrystalline silicon layers 14′ that are alternately stacked by epitaxial growth. The silicon germanium layers 12 may be sacrificial layers, and the monocrystalline silicon layers 14′ may be recess target layers. The silicon germanium layers 12 may correspond to the first layers 12A or the third layers 12B of FIG. 4, and the monocrystalline silicon layers 14′ may correspond to the fourth layers 14 of FIG. 4. Unlike the stacked structure SB of FIG. 4, the stacked structure SB10 may be formed of an alternating stack of silicon germanium layers 12 and monocrystalline silicon layers 14′.

Referring to FIG. 29B, a hard mask layer pattern 15 may be formed over the stacked structure SB10.

Subsequently, the stacked structure SB may be etched using the hard mask layer pattern 15 as an etch barrier. As a result, a plurality of first and second sacrificial vertical openings 16′ and 17′ may be formed in the stacked structure SB10.

Referring to FIG. 29C, dummy channel patterns 14A′ and horizontal recesses 19 may be formed. The dummy channel patterns 14A′ and the horizontal recesses 19 may be formed by a recess process of the silicon germanium layers 12 and the monocrystalline silicon layers 14′ of FIG. 29B. Specifically, first the silicon germanium layers 12 may be removed, and after the silicon germanium layers 12 are removed, a recess process of the monocrystalline silicon layers 14′ may be performed to thin out the monocrystalline silicon layers 14′ and form the thinner preliminary horizontal layers 14A′. The preliminary horizontal layers 14A′ may correspond to the dummy channel patterns 14A of FIG. 6.

To recess the silicon germanium layers 12, a wet etching process or a dry etching process may be used. The silicon germanium layers 12 may be etched using an etchant or an etching gas having a selectivity with respect to the monocrystalline silicon layers 14′.

For the recess process of the monocrystalline silicon layers 14′ for forming the dummy channel patterns 14A, for example, HSC1 (Hot SC-1) may be used. HSC1 may include a solution of ammonium hydroxide (NH₄OH), hydrogen peroxide (H₂O₂) and water (H₂O) mixed at a ratio of approximately 1:4:20. The monocrystalline silicon layers 14′ may be selectively etched using HSC1.

After the dummy channel patterns 14A are formed, the first and second sacrificial vertical openings may be expanded as indicated by reference numerals ‘16’ and ‘17’. While the dummy channel patterns 14A are formed, the surface of the lower structure 11 may be recessed to a predetermined depth (see a reference numeral ‘11A’). As a result, the depth of the first and second sacrificial vertical openings 16 and 17 may increase.

Subsequently, a series of the processes illustrated in FIGS. 7 to 25 may be performed.

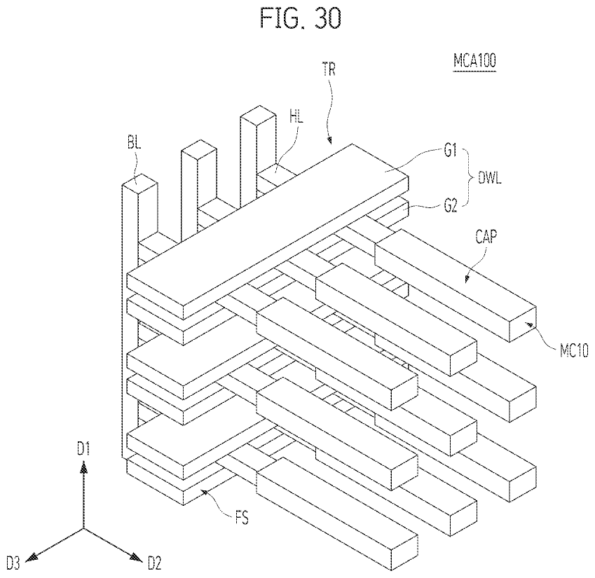

FIGS. 30 to 32 are perspective views illustrating memory cell arrays in accordance with other embodiments of the present invention. The memory cell arrays MCA100, MCA200, and MCA300 may be similar to the memory cell array MCA of FIG. 3A. Hereinafter, detailed descriptions of the constituent elements also appearing in FIG. 3A will be omitted.

Referring to FIG. 30, the memory cell array MCA100 may include a plurality of memory cells MC10.

The memory cell array MCA100 may include a three-dimensional array of memory cells MC10. The three-dimensional array of the memory cells MC10 may include a column array of memory cells MC10 and a row array of memory cells MC10. The column array of the memory cells MC10 may include a plurality of memory cells MC10 that are stacked in the first direction D1. The row array of the memory cells MC10 may include a plurality of memory cells MC10 that are horizontally arranged in the second direction D2 and the third direction D3.

Each memory cell MC10 may include a first conductive line BL, a switching element TR, and a data storage element CAP. As for the detailed descriptions on the first conductive line BL and the data storage element CAP, the above-described embodiments may also be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G2 that are facing each other with the horizontal layer HL interposed therebetween. As illustrated in FIG. 3B, an inter-level dielectric layer GD may be formed in the upper and lower surfaces of the horizontal layer HL.

Each of the upper horizontal line G1 and the lower horizontal line G2 may include a pair of flat sidewalls FS extending in the third direction D3. The flat sidewalls FS may refer to vertical sidewalls. The flat side wall FS may have a linear shape extending in the third direction D3.

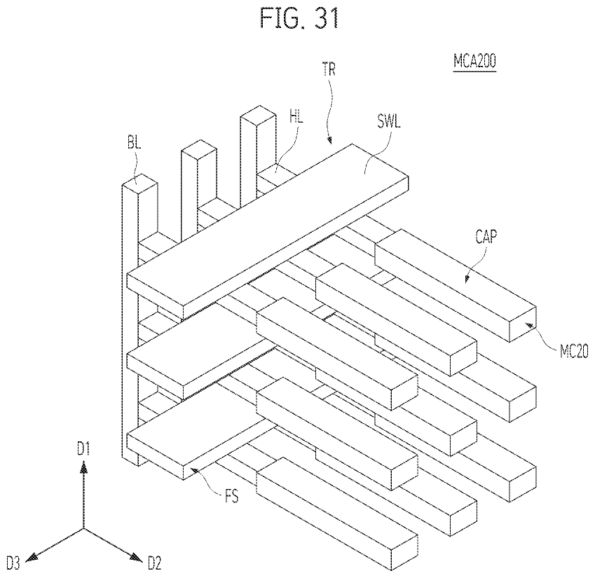

Referring to FIG. 31, the memory cell array MCA200 may include a plurality of memory cells MC20.

The memory cell array MCA200 may include a three-dimensional array of memory cells MC20. The three-dimensional array of memory cells MC20 may include a column array of memory cells MC20 and a row array of memory cells MC20. The column array of the memory cells MC20 may include a plurality of memory cells MC20 that are stacked in the first direction D1. The row array of the memory cells MC20 may include a plurality of memory cells MC20 that are horizontally arranged in the second direction D2 and the third direction D3.

Each memory cell MC20 may include the first conductive line BL, the switching element TR, and the data storage element CAP. As for the detailed descriptions on the first conductive line BL and the data storage element CAP, the above-described embodiments may also be referred to.

The switching element TR may include a horizontal layer HL and a second conductive line SWL. The horizontal layer HL may extend in the second direction D2. The second conductive line SWL may extend in the third direction D3.

The second conductive line SWL may have a single structure. For example, the second conductive line SWL may be disposed over the horizontal layer HL. Referring to FIG. 3B, an inter-level dielectric layer GD may be formed between the upper surface of the horizontal layer HL and the second conductive line SWL. According to another embodiment of the present invention, the second conductive line SWL may be disposed below the horizontal layer HL.

The second conductive line SWL may include a pair of flat sidewalls FS extending in the third direction D3. The flat sidewalls FS may refer to a vertical sidewall.

According to another embodiment of the present invention, the second conductive line SWL may include a channel overlapping portion WLP and a channel non-overlapping portion NOL, as illustrated in FIG. 1C.

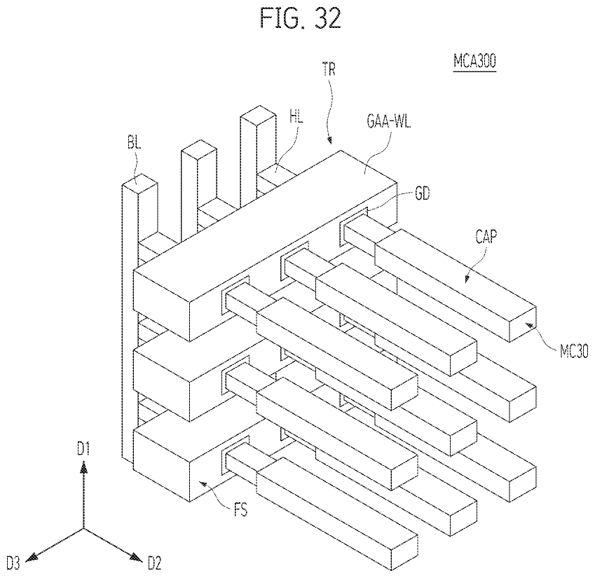

Referring to FIG. 32, the memory cell array MCA300 may include a plurality of memory cells MC30.

The memory cell array MCA300 may include a three-dimensional array of memory cells MC30. The three-dimensional array of memory cells MC30 may include a column array of memory cells MC30 and a row array of memory cells MC30. The column array of the memory cells MC30 may include a plurality of memory cells MC30 that are stacked in the first direction D1. The row array of the memory cells MC30 may include a plurality of memory cells MC30 that are horizontally arranged in the second direction D2 and the third direction D3.

Each memory cell MC30 may include a first conductive line BL, a switching element TR, and a data storage element CAP. As for the detailed descriptions on the first conductive line BL and the data storage element CAP, the above-described embodiments may also be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may have a gate all around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat sidewalls FS extending in the third direction D3. The flat sidewalls FS may refer to vertical sidewalls.

According to an embodiment of the present invention, each memory cell may include a first conductive line BL extending horizontally in the third direction D3, a second conductive line DWL extending vertically in the first direction D1, and a horizontal layer HL extending horizontally in the second direction D2. The second conductive line DWL may have a double structure. In an embodiment, the second conductive line DWL may be replaced by a single structure or a gate-all-around structure.

According to an embodiment of the present invention, since high-temperature processes are performed before a channel layer replacement process, deterioration of a channel layer that may be caused due to the thermal processes may be prevented.

According to an embodiment of the present invention, since a gate dielectric layer is formed through a thermal oxidation process, the quality of the gate dielectric layer may be improved.

While the present invention has been described with respect to specific embodiments, it will be apparent to those skilled in the art that various changes and modifications may be made without departing from the technical concepts and scope of the invention as disclosed herein and also defined in the following claims. Furthermore, the embodiments may be combined to form additional embodiments.

What is claimed is:

1. A method for fabricating a semiconductor device, the method comprising:
forming a cell mold including a dummy channel pattern and a plurality of mold layers over a lower structure;
forming a horizontal conductive line that intersects with the dummy channel pattern;
forming a dummy channel layer by trimming the dummy channel pattern;
forming a data storage element that is coupled to a first side of the dummy channel layer;
replacing the dummy channel layer with a channel layer; and
forming a vertical conductive line that is coupled to a second side of the channel layer.

2. The method of claim 1, wherein the replacing the dummy channel layer with the channel layer includes:
forming a channel level gap by removing the dummy channel layer;
forming a channel material layer over the channel level gap; and
forming the channel layer by selectively removing the channel material layer.

3. The method of claim 2, wherein the dummy channel pattern and the dummy channel layer include a silicon material, and
the channel layer includes an oxide semiconductor material.

4. The method of claim 1, further comprising:
before the forming of the horizontal conductive line that intersects with the dummy channel pattern,
forming a gate dielectric layer on top and bottom surfaces of the dummy channel pattern, individually.

5. The method of claim 4, wherein the forming the gate dielectric layer includes
exposing the top and bottom surfaces of the dummy channel pattern to a thermal oxidation process.

6. The method of claim 1, wherein the forming the horizontal conductive line that intersects with the dummy channel pattern includes:
forming horizontal level recesses that intersect with the dummy channel pattern by removing the mold layers of the cell mold;
forming a conductive material over the horizontal level recesses; and
forming the horizontal conductive line by selectively etching the conductive material.

7. The method of claim 1, wherein the forming the cell mold including the dummy channel pattern includes:
forming the dummy channel pattern over the lower structure;
forming a first cell dielectric layer that surrounds the dummy channel pattern; and
forming a second cell dielectric layer that surrounds the first cell dielectric layer.

8. The method of claim 7, wherein the first cell dielectric layer includes silicon nitride, and
the second cell dielectric layer includes silicon oxide.

9. The method of claim 1, wherein the forming the cell mold including the dummy channel pattern includes:
forming a stacked structure that includes a dummy channel material layer over the lower structure and sacrificial layers respectively disposed on the top and bottom surfaces of the dummy channel material layer;
forming openings by etching portions of the stacked structure;
removing the sacrificial layers through the openings; and
forming the dummy channel pattern by thinning the dummy channel material layer through the openings.

10. The method of claim 9, wherein the sacrificial layers include a silicon layer, a silicon germanium layer, or a combination thereof.

11. The method of claim 1, wherein the dummy channel pattern includes a silicon material, and
the channel layer includes an oxide semiconductor material.

12. The method of claim 1, wherein the replacing the dummy channel layer with the channel layer includes:
forming a channel level gap by removing the dummy channel layer;
conformally forming a channel material layer over the channel level gap;
forming an inner gap-fill layer over the channel material layer; and
forming the channel layer by selectively removing the channel material layer.

13. The method of claim 12, wherein the channel material layer includes an oxide semiconductor material, and
the inner gap-fill layer includes a dielectric material.

14. A method for fabricating a semiconductor device, the method comprising:
forming a cell mold including a dummy channel pattern over a lower structure and a pair of cell dielectric layers disposed in upper and lower portions of the dummy channel pattern;
forming a pair of horizontal level recesses that expose top and bottom surfaces of the dummy channel pattern by recessing the pair of the cell dielectric layers;
forming gate dielectric layers on the exposed top and bottom surfaces of the dummy channel pattern;
forming first and second horizontal conductive lines that fill the pair of the horizontal level recesses over the gate dielectric layers;
forming a dummy channel layer by trimming the dummy channel pattern;
forming a channel level gap between the first horizontal conductive line and the second horizontal conductive line by removing the dummy channel layer; and
forming a channel layer in the channel level gap.

15. The method of claim 14, wherein the dummy channel layer includes a silicon material, and
the channel layer includes an oxide semiconductor material.

16. The method of claim 14, wherein the forming the gate dielectric layers includes:
exposing the exposed top and bottom surfaces of the dummy channel pattern to a thermal oxidation process.

17. The method of claim 14, wherein the forming the channel layer includes:
forming a channel material layer that fills the channel level gap; and
forming the channel layer by selectively removing the channel material layer.

18. The method of claim 14, wherein the forming the channel layer includes:
conformally forming a channel material layer over the channel level gap;
forming an inner gap-fill layer over the channel material layer; and
forming the channel layer by selectively removing the channel material layer.

19. The method of claim 14, further comprising:
forming a data storage element that is coupled to the dummy channel layer, after forming the dummy channel layer.

20. The method of claim 14, further comprising:
forming a vertical conductive line that is coupled to the channel layer, after forming the channel layer.

21. A semiconductor device comprising:
a lower structure;
a horizontal layer disposed over the lower structure;
horizontal conductive lines disposed in upper and lower portions of the horizontal layer, respectively;
a gate dielectric layer between the horizontal conductive line and the horizontal layer;
a vertical conductive line that is coupled to a first side of the horizontal layer; and
a data storage element that is coupled to a second side of the horizontal layer,
wherein the horizontal layer includes:
a channel layer having an inner space; and
an inner gap-fill layer that fills the inner space of the channel layer.

22. The semiconductor device of claim 21, wherein the channel layer has a horizontally oriented cup shape.

23. The semiconductor device of claim 21, wherein the channel layer includes an oxide semiconductor material.

24. The semiconductor device of claim 21, wherein the gate dielectric layer includes an oxide of a silicon material.

25. The semiconductor device of claim 21, further comprising:
a first contact node between the horizontal layer and the data storage element; and
a second contact node between the horizontal layer and the vertical conductive line.
